(19) United States
(12) Patent Application Publication
(10) Pub. No.: US 2024/0015978 A1
(43) Pub. Date: Jan. 11, 2024

(54) SEMICONDUCTOR MEMORY DEVICES

(71) Applicant: Samsung Electronics Co., Ltd., Suwon-si, Gyeonggi-do (KR)

(72) Inventors: Siyeon Cho, Suwon-si (KR); Taeyoung Kim, Suwon-si (KR); Hyunmog Park, Suwon-si (KR); Bongyong Lee, Suwon-si (KR); Yukio Hayakawa, Suwon-si (KR)

(21) Appl. No.: 18/320,816

(22) Filed: May 19, 2023

(30) Foreign Application Priority Data
Jul. 5, 2022 (KR) 10-2022-0082342

(51) Int. Cl. H10B 51/20; H10B 51/10; H01L 23/528

(52) U.S. Cl. CPC H10B 51/20; H10B 51/10; H01L 23/5283

(57) ABSTRACT

Disclosed are semiconductor memory devices and electronic systems including the same. The semiconductor memory device may include a vertical channel perpendicular to a top surface of a substrate, word lines disposed on a first side of the vertical channel and vertically stacked on the substrate, back-gate electrodes disposed on a second side of the vertical channel and vertically stacked on the substrate, a ferroelectric layer disposed between the word lines and the first side of the vertical channel, a first intermediate insulating layer disposed between the ferroelectric layer and the first side of the vertical channel, and a second intermediate insulating layer disposed between the back-gate electrodes and the second side of the vertical channel.

### CROSS-REFERENCE TO RELATED APPLICATIONS

This U.S. non-provisional patent application claims priority under 35 U.S.C. § 119 to Korean Patent Application No. 10-2022-0082342, filed on Jul. 5, 2022, in the Korean Intellectual Property Office, the entire contents of which are hereby incorporated by reference.

### BACKGROUND

The present disclosure relates to semiconductor memory devices and electronic systems including the same.

A semiconductor device capable of storing a large capacity of data is required as a part of an electronic system. Accordingly, many studies are being conducted to increase the data storage capacity of the semiconductor device. For example, semiconductor devices, in which memory cells are three-dimensionally arranged, are being suggested.

### SUMMARY

Some implementations of the present disclosure provide a semiconductor memory device having a high integration density and a high operation speed.

Some implementations of the present disclosure provide an electronic system including the semiconductor memory device.

According to some implementations of the present disclosure, a semiconductor memory device may include a vertical channel perpendicular to a top surface of a substrate, word lines disposed on a first side of the vertical channel and vertically stacked on the substrate, back-gate electrodes disposed on a second side of the vertical channel and vertically stacked on the substrate, a ferroelectric layer disposed between the word lines and the first side of the vertical channel, a first intermediate insulating layer disposed between the ferroelectric layer and the first side of the vertical channel, and a second intermediate insulating layer disposed between the back-gate electrodes and the second side of the vertical channel.

According to some implementations of the present disclosure, a semiconductor memory device may include a first stack provided on a substrate and extended in a first direction, the first stack including word lines which are vertically stacked, a second stack provided on the substrate and extended in the first direction, the second stack including back-gate electrodes which are vertically stacked, vertical channels spaced apart from each other in the first direction, between the first stack and the second stack, ferroelectric layers disposed between the vertical channels and the first stack, first intermediate insulating layers disposed between the ferroelectric layer and the vertical channels, and second intermediate insulating layers disposed between the vertical channels and the second stack.

According to some implementations of the present disclosure, a semiconductor memory device may include a first stack provided on substrate and extended in a first direction, the first stack including vertically-stacked word lines, a second stack provided on the substrate and extended in the first direction, the second stack including vertically-stacked back-gate electrodes, a vertical insulating layer provided between the first stack and the second stack and extended in the first direction, and vertical structures provided to penetrate the first stack. Each of the vertical structures may include a vertical channel perpendicular to a top surface of the substrate, a ferroelectric layer between the vertical channel and the first stack, and an intermediate insulating layer between the ferroelectric layer and the vertical channel. The vertical structures may have first side surfaces that are in contact with the vertical insulating layer.

According to some implementations of the present disclosure, an electronic system may include a semiconductor memory device including a peripheral circuit structure, a cell array structure, and an input/output pad, and a controller, which is electrically connected to the semiconductor device through the input/output pad and is used to control the semiconductor memory device. The input/output pad may be electrically connected to the peripheral circuits. The peripheral circuit structure may include peripheral circuits, which are integrated on a semiconductor substrate, and peripheral lines, which are connected to the peripheral circuits. The cell array structure may include a vertical channel perpendicular to a top surface of the semiconductor substrate, word lines disposed near a first side of the vertical channel and vertically stacked on the substrate, back-gate electrodes disposed near a second side of the vertical channel and vertically stacked on the substrate, a ferroelectric layer disposed between the word lines and the first side of the vertical channel, a first intermediate insulating layer disposed between the ferroelectric layer and the first side of the vertical channel, and a second intermediate insulating layer disposed between the back-gate electrodes and the second side of the vertical channel.

### BRIEF DESCRIPTION OF THE DRAWINGS

FIG. 1 is a circuit diagram illustrating a cell array of a semiconductor memory device according to some implementations of the present disclosure.

FIG. 2 is a diagram illustrating a unit memory cell according to some implementations of the present disclosure.

FIG. 3 is a perspective view illustrating a semiconductor memory device according to some implementations of the present disclosure.

FIG. 4 is a plan view illustrating a semiconductor memory device according to some implementations of the present disclosure.

FIG. 5 is a sectional view taken along a line A-A′ of FIG. 4.

FIG. 6A is an enlarged sectional view illustrating a portion ‘P1’ of FIG. 5.

FIG. 6B is a diagram illustrating an example condition of voltages for operations of a semiconductor memory device according to some implementations of the present disclosure.

FIG. 7 is a perspective view illustrating a semiconductor memory device according to some implementations of the present disclosure.

FIG. 8 is a plan view illustrating a semiconductor memory device according to some implementations of the present disclosure.

FIG. 9 is a sectional view taken along line an A-A′ of FIG. 8.

FIG. 10 is an enlarged sectional view illustrating a portion ‘P2’ of FIG. 9.

FIG. 11 is a plan view illustrating a semiconductor memory device according to some implementations of the present disclosure.

FIG. 12 is a sectional view taken along a line A-A′ of FIG. 11.

FIG. 13 is an enlarged sectional view illustrating a portion ‘P3’ of FIG. 12.

FIG. 14 is a perspective view illustrating a semiconductor memory device according to some implementations of the present disclosure.

FIG. 15 is a plan view illustrating a semiconductor memory device according to some implementations of the present disclosure.

FIG. 16 is a sectional view taken along a line A-A′ of FIG. 15.

FIGS. 17A and 17B are enlarged sectional views illustrating a portion ‘P4’ of FIG. 16.

FIG. 18 is a plan view illustrating a semiconductor memory device according to some implementations of the present disclosure.

FIG. 19 is a sectional view taken along a line A-A′ of FIG. 18.

FIG. 20 is an enlarged sectional view illustrating a portion ‘P5’ of FIG. 19.

FIG. 21 is a plan view illustrating a semiconductor memory device according to some implementations of the present disclosure.

FIG. 22 is a sectional view taken along a line A-A′ of FIG. 21.

FIG. 23 is an enlarged sectional view illustrating a portion ‘P6’ of FIG. 22.

FIGS. 24A to 28A are plan views illustrating a method of fabricating a semiconductor memory device according to some implementations of the present disclosure.

FIGS. 24B to 28B are sectional views which are taken along lines A-A′ of FIGS. 24A to 28A to illustrate a method of fabricating a semiconductor memory device according to some implementations of the present disclosure.

FIGS. 29A to 29D are sectional views which are taken along the line A-A′ of FIG. 8 to illustrate a method of fabricating a semiconductor memory device according to some implementations of the present disclosure.

FIG. 30 is a schematic diagram schematically illustrating an electronic system including a semiconductor memory device according to some implementations of the present disclosure.

FIG. 31 is a perspective view schematically illustrating an electronic system including a semiconductor memory device according to some implementations of the present disclosure.

FIGS. 32 and 33 are schematic sectional views illustrating semiconductor packages according to implementations of the present disclosure.

FIG. 34 is a sectional view illustrating a semiconductor memory device according to some implementations of the present disclosure.

### DETAILED DESCRIPTION

Example implementations will now be described more fully with reference to the accompanying drawings, in which example implementations are shown.

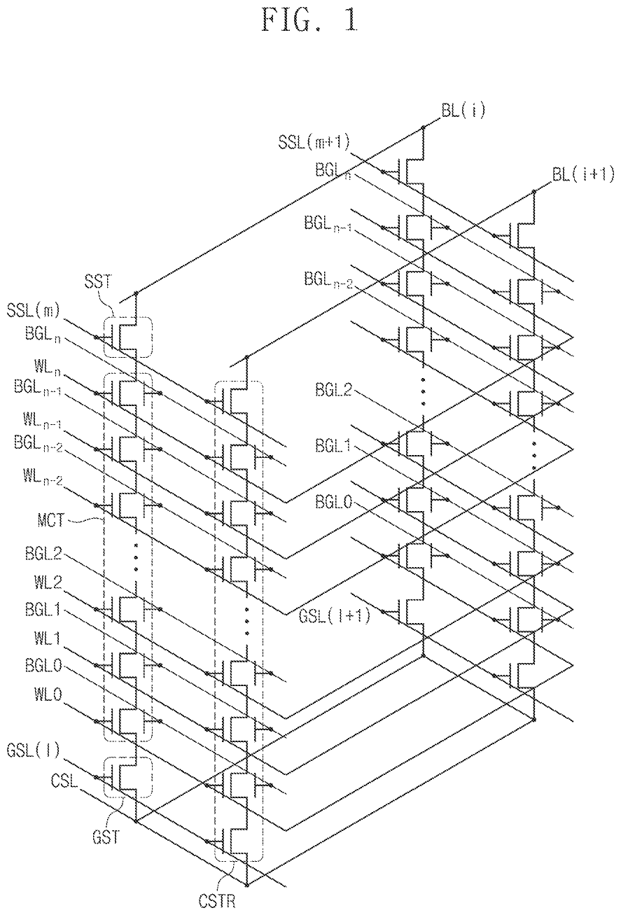

FIG. 1 is a circuit diagram illustrating a cell array of a semiconductor memory device according to some implementations of the present disclosure.

Referring to FIG. 1, a cell array of a semiconductor memory device according to some implementations of the present disclosure may include bit line BL(i) and BL(i+1), a common source line CSL, word lines WL0, WL1, . . . , and WLn, back-gate electrodes BGL0, BGL1, . . . , and BGLn, string selection lines (or upper selection lines) SSL(m) or SSL(m+1), ground selection lines (or lower selection lines) GSL(l) and GSL(l+1), and cell strings CSTR between the bit lines BL(i) and BL(i+1) and the common source line CSL.

The bit lines BL(i) and BL(i+1) may be two-dimensionally arranged, and a plurality of cell strings CSTR may be connected in parallel to each of them. The cell strings CSTR may be connected in common to the common source line CSL. For example, a plurality of the cell strings CSTR may be disposed between a plurality of bit lines BL(i) and BL(i+1) and one common source line CSL.

In some implementations, each of the cell strings CSTR may be composed of a ground selection transistor GST coupled to the common source line CSL, a string selection transistor SST coupled to the bit line BL(i) or BL(i+1), and a plurality of memory cells MCT disposed between the ground and string selection transistors GST and SST. The ground selection transistor GST, the string selection transistor SST, and the memory cells MCT may be connected in series. In some implementations, each of the cell strings CSTR may include one or more string selection transistors SST and one or more ground selection transistors GST.

The ground selection lines GSL(l) and GSL(l+1), the word lines WL0, WL1, . . . , and WLn, and the string selection lines SSL(m) and SSL(m+1) may be used as gate electrodes of the ground selection transistor GST, the memory cells MCT, and the string selection transistors SST, respectively.

The string selection lines SSL(m) and SSL(m+1) may be used to control an electric connection between the bit lines BL(i) and BL(i+1) and the cell strings CSTR, and the ground selection line GSL(l) may be used to control an electric connection between the cell strings CSTR and the common source line CSL. In addition, the word lines WL0 to WLn and the back-gate lines BGL0 to BGLn may be used to control the memory cells MCT. Ones of the memory cells MCT, which are located at the same level, may be connected in common to one of the word lines WL0 to WLn and one of the back-gate lines BGL0 to BGLn.

One of the cell strings CSTR may be selected by a selected one of the bit lines BL(i) and BL(i+1) and a selected one of the string selection lines SSL(m) and SSL(m+1). In addition, one of the memory cells MCT in the selected one cell string CSTR may be selected by a selected one of the word lines WL0 to WLn and a selected one of the back-gate lines BGL0 to BGLn.

In some implementations, each of the memory cells MCT may include a data storage element including a ferroelectric material. By using the data storage element including the ferroelectric material, it may be possible to realize a fast semiconductor memory device that can be operated with low power. A voltage difference between one of the word lines WL0 to WLn and a channel region may be adjusted to cause a change in polarization of a dipole of the ferroelectric material in each memory cell MCT, and this may be used to perform a data writing or erasing operation on each memory cell MCT.

In some implementations, program and erase operations on each memory cell MCT may be performed by voltages applied to the word lines WL0 to WLn, and a read operation on each memory cell MCT may be performed by voltages applied to the back-gate lines BGL0 to BGLn. Thus, it may be possible to separate a path for a read operation from a path for the program or write operation in the memory cell and thereby to reduce a data disturbance issue in the data read operation.

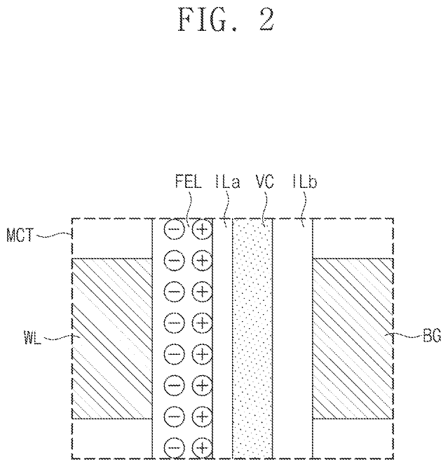

FIG. 2 is a diagram illustrating a unit memory cell according to some implementations of the present disclosure.

Referring to FIGS. 1 and 2, each memory cell MCT may include a vertical channel VC, a word line WL, a back-gate electrode BG, a ferroelectric layer FEL, a first intermediate insulating layer or inter-insulating layer Ila, and a second intermediate insulating layer ILb.

In each memory cell MCT, the vertical channel VC may be disposed between the word line WL and the back-gate electrode BG. The vertical channel VC may be formed of or include at least one semiconductor material (e.g., silicon (Si), germanium (Ge), or compounds thereof). For example, in some implementations, the vertical channel VC may be formed of or include at least one oxide semiconductor material (e.g., InₓGa_{y}Zn_{z}O (IGZO)).

The word line WL and the back-gate electrode BG may be provided to cross the vertical channel VC. A portion (e.g., an end) of the vertical channel VC (e.g., a drain electrode of a memory cell) may be connected to a bit line BL, and another portion (e.g., an opposite end) of the vertical channel VC (e.g., a source electrode of the memory cell) may be connected to the common source line CSL.

Each memory cell MCT may include the ferroelectric layer FEL, which is disposed between the word line WL and the vertical channel VC and is used as a memory layer (or a data storage layer). In each memory cell MCT, the ferroelectric layer FEL may have a non-centrosymmetric charge distribution and thereby may have a spontaneous dipole (i.e., spontaneous polarization). The ferroelectric layer FEL may have a remnant polarization, which is caused by the dipole, even when there is no external electric field. Furthermore, a direction of the polarization may be switched by an external electric field. For example, the ferroelectric layer FEL may have a positive or negative polarization state, and the polarization state may be changed by an electric field exerted on the ferroelectric layer FEL during a program operation. Even when a power is interrupted, the polarization state of the ferroelectric layer FEL may be maintained, and thus, the semiconductor memory device may be operated as a nonvolatile memory device. In some implementations, the polarization state of the ferroelectric layer FEL may be controlled by a difference in voltage between the channel region and the back-gate electrode. The ferroelectric layer FEL may be formed of a hafnium-containing dielectric material (e.g., HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂), but some implementations may include non-hafnium-containing material(s) for the ferroelectric layer FEL.

The first intermediate insulating layer ILa may be disposed between the vertical channel VC and the ferroelectric layer FEL. The second intermediate insulating layer ILb may be disposed between the vertical channel VC and the back-gate electrode BG. The second intermediate insulating layer ILb may have a thickness (e.g., a thickness in a direction from the vertical channel VC to the back-gate electrode BG) which is substantially equal to or larger than that of the first intermediate insulating layer ILa.

The first and second intermediate insulating layers ILa and ILb may be formed of an insulating material different from the ferroelectric layer FEL, and in some implementations, they may be formed of a non-ferroelectric material. The first and second intermediate insulating layers ILa and ILb may be formed of or include at least one of high-k dielectric materials, silicon oxide, silicon nitride, or silicon oxynitride and may have a single- or multi-layered structure. In some implementations, the high-k dielectric materials may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

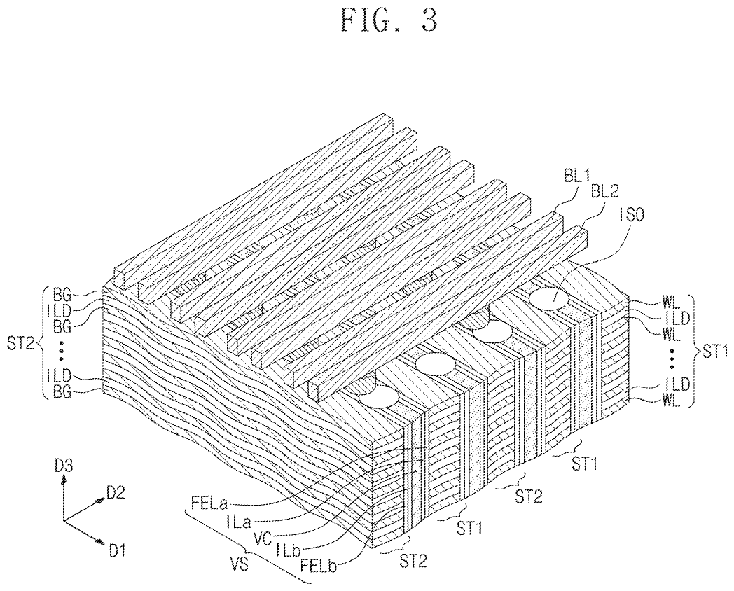

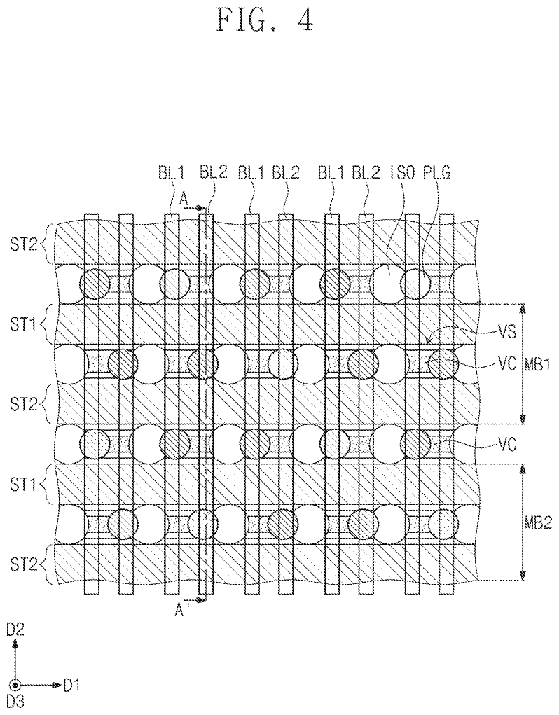

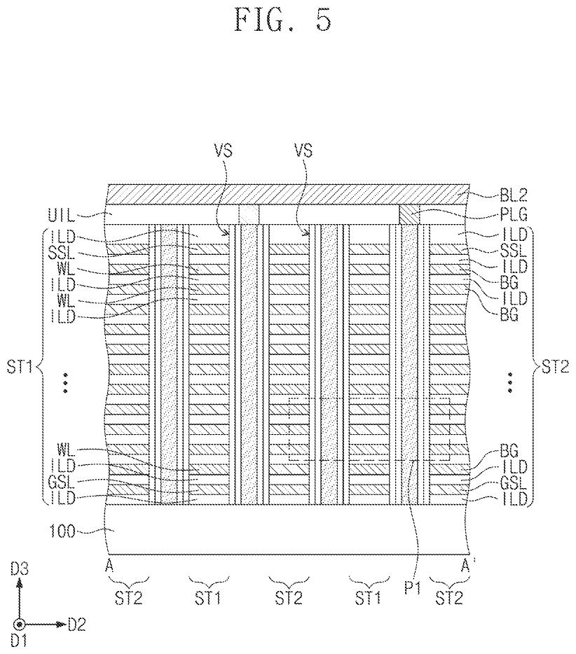

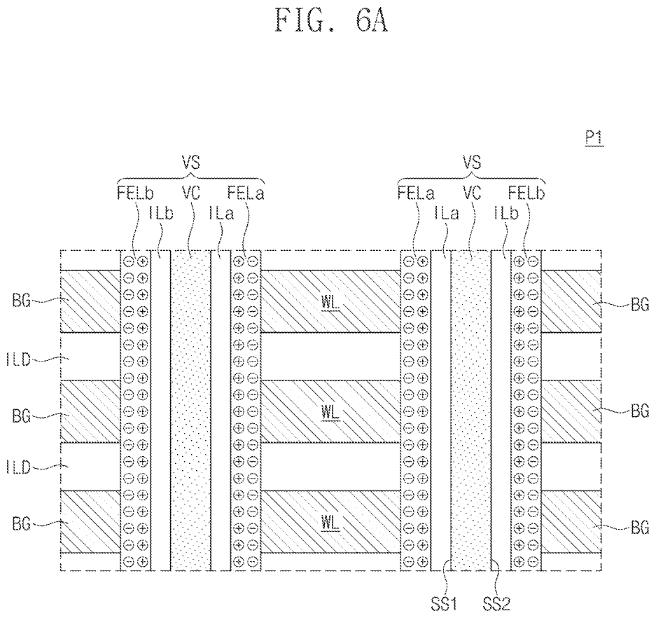

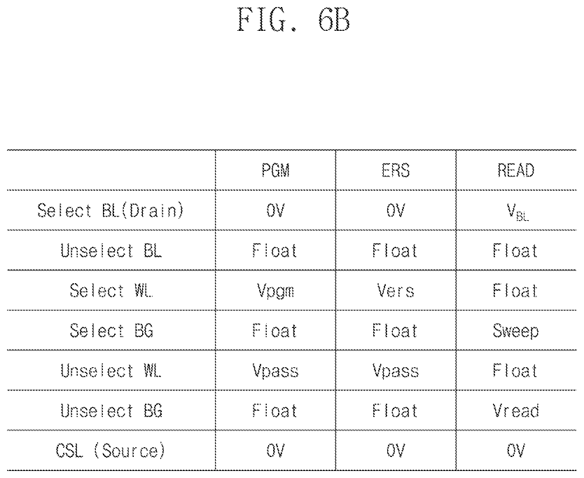

FIG. 3 is a perspective view illustrating a semiconductor memory device according to some implementations of the present disclosure. FIG. 4 is a plan view illustrating a semiconductor memory device according to some implementations of the present disclosure. FIG. 5 is a sectional view taken along a line A-A′ of FIG. 4. FIG. 6A is an enlarged sectional view illustrating a portion ‘P1’ of FIG. 5. FIG. 6B is a diagram illustrating an example condition of voltages for operations of a semiconductor memory device according to some implementations of the present disclosure, e.g., the device of FIGS. 3-6A.

Referring to FIGS. 3, 4, and 5, a semiconductor memory device may include a first memory block MB1 and a second memory block MB2, and each of the first and second memory blocks MB1 and MB2 may include a first stack ST1, a second stack ST2, vertical structures VS, insulating isolation patterns ISO, and bit lines BL.

In some implementations, the cell strings CSTR of FIG. 1 may be integrated on a substrate 100, and the first and second stacks ST1 and ST2 and the vertical structures VS may constitute the cell strings CSTR of FIG. 1.

In detail, the substrate 100 may be formed of or include at least one of semiconductor materials, insulating materials, or conductive materials. The substrate 100 may be formed of or include a semiconductor material, which may be doped to have a particular conductivity type (e.g., n-type), and/or an undoped or intrinsic semiconductor material. The substrate 100 may have one or more of polycrystalline, amorphous, and/or single-crystalline structures. The substrate 100 may include an impurity region (or a well region), which may be used as the common source line CSL of FIG. 1.

The first and second stacks ST1 and ST2 may be disposed on the substrate 100 and may extend in a first direction D1 parallel to a top surface of the substrate 100. The first and second stacks ST1 and ST2 may be disposed in an alternating arrangement (e.g., ST1, then ST2, then ST1, etc.) in a second direction D2, which is not parallel to the first direction D1 and is parallel to the top surface of the substrate 100. For example, the second direction D2 may be perpendicular to the first direction D1.

Each of the first stacks ST1 may include word lines WL and interlayer insulating layers ILD, which are stacked in an alternating arrangement in a third direction D3 (e.g., a vertical direction) perpendicular to the top surface of the substrate 100. Each of the second stacks ST2 may include back-gate electrodes BG and interlayer insulating layers ILD, which are stacked in an alternating arrangement in the third direction D3. In some implementations, as shown in FIG. 5, at least some of the back-gate electrodes BG may be located at the same level as a corresponding one of the word lines WL and may have the same thickness as the corresponding one of the word lines WL.

The word lines WL and the back-gate electrodes BG may be formed of or include doped polysilicon or a metallic material whose specific resistance is lower than that of the polysilicon. The word lines WL and the back-gate electrodes BG may be formed to have the same thickness and may be formed of the same conductive material. The word lines WL and the back-gate electrodes BG may be formed of or include at least one of, for example, doped semiconductor materials (e.g., doped silicon), metals (e.g., tungsten, copper, and aluminum), conductive metal nitrides (e.g., titanium nitride and tantalum nitride), or transition metals (e.g., titanium and tantalum).

The interlayer insulating layers ILD of the first and second stacks ST1 and ST2 may be formed of the same insulating material and may have the same thickness. The interlayer insulating layers ILD may include a silicon oxide layer and/or a low-k dielectric layer.

Each of the first and second stacks ST1 and ST2 may include a ground selection line GSL, which is located below the lowermost one of the word lines WL or the lowermost one of the back-gate electrodes BG, and a string selection line SSL, which is located on (e.g., above) the uppermost one of the word lines WL or the uppermost one of the back-gate electrodes BG.

In some implementations, between adjacent ones of the first and second stacks ST1 and ST2, the vertical structures VS may be disposed to be spaced apart from each other in the first direction D1.

The vertical structures VS may extend (e.g., have a longest dimension) in the third direction D3, on the substrate 100. The vertical structures VS may be provided to cross/extend by side surfaces of the word lines WL and side surfaces of the back-gate electrodes BG.

In more detail, referring to FIGS. 5 and 6A, each of the vertical structures VS may include the vertical channel VC, first and second ferroelectric layers FELa and FELb, and the first and second intermediate insulating layers ILa and ILb.

The vertical channel VC may extend in the third direction D3 and may be connected to (e.g., in contact with) the substrate 100. The vertical channel VC may be formed of or include at least one of semiconductor materials (e.g., silicon (Si), germanium (Ge), or compounds thereof). The vertical channel VC including the semiconductor material may be used as channel regions of the string and ground selection transistors SST and GST and the memory cells MCT described with reference to FIG. 1.

The vertical channel VC may have a first side surface SS1 and a second side surface SS2, which are opposite to each other in the second direction D2. As an example, the vertical channel VC may be a pillar-shaped pattern extending in the third direction D3. The first side surface SS1 of the vertical channel VC may be in contact with the first intermediate insulating layer ILa, and the second side surface SS2 of the vertical channel VC may be in contact with the second intermediate insulating layer ILb.

The first ferroelectric layer FELa, which is used as a data storage layer, may be disposed between the word lines WL and the first side surface SS1 of the vertical channel VC. The second ferroelectric layer FELa may be disposed between the back-gate electrodes BG and the second side surface SS2 of the vertical channel VC.

In some implementations, the first and second ferroelectric layers FELa and FELb may be formed of or include a ferroelectric material, which has a polarized property when an electric field is applied thereto. The ferroelectric material may be formed of a hafnium-containing dielectric material. The first and second ferroelectric layers FELa and FELb may include HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂, and/or another ferroelectric material.

In some implementations, the first and second ferroelectric layers FELa and FELb may be formed in a symmetric shape. For example, the first and second ferroelectric layers FELa and FELb may be formed of the same ferroelectric material and may have the same thickness.

The first intermediate insulating layer ILa may be disposed between the first ferroelectric layer FELa and the first side surface SS1 of the vertical channel VC. The second intermediate insulating layer ILb may be disposed between the second ferroelectric layer FELb and the second side surface SS2 of the vertical channel VC.

The first and second intermediate insulating layers ILa and ILb may be formed of an insulating material different from the ferroelectric layer FEL, and in some implementations, they may be formed of a non-ferroelectric material. The first and second intermediate insulating layers ILa and ILb may be formed of or include at least one of, for example, high-k dielectric materials, silicon oxide, silicon nitride, or silicon oxynitride and may have a single- or multi-layered structure. In some implementations, the high-k dielectric materials may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some implementations, the first and second intermediate insulating layers ILa and ILb may be formed in a symmetric shape, For example, the first and second intermediate insulating layers ILa and ILb may be formed of the same insulating material and may have the same thickness.

The insulating isolation patterns ISO may be disposed between adjacent first and second stacks ST1 and ST2 and may be spaced apart from each other in the first direction D1. The insulating isolation patterns ISO may be respectively disposed between the vertical channels VC, which are adjacent to each other in the first direction D1. The insulating isolation patterns ISO may extend (e.g., have a longest dimension) in the third direction D3, and may be disposed on the substrate 100. When measured in the second direction D2, a width of each insulating isolation pattern ISO may be larger than a width of the vertical channel VC, e.g., a width of a vertical channel VC adjacent to the insulation isolation pattern ISO. The insulating isolation pattern ISO may be formed of or include at least one of insulating materials, silicon oxide materials, silicon oxynitride materials. The insulating isolation pattern ISO may be formed by a spin-on-glass (SOG) technique or another technique.

An upper insulating layer UIL may be disposed on the first and second stacks ST1 and ST2 and the vertical structures VS.

Bit lines BL1 and BL2 may be provided on the upper insulating layer UIL and may extend in the second direction D2 to cross the first and second stacks ST1 and ST2. The bit lines BL1 and BL2 may be coupled to the vertical channel VC of each vertical structure VS through contact plugs PLG that may extend through the upper insulating layer UIL.

A pair of bit lines BL1 and BL2 may be disposed over each of the vertical structures VS. A line width of each of the bit lines BL1 and BL2 may be smaller than half of a width of the vertical structure VS in the first direction D1.

In some implementations, a first bit line BL1 may be connected in common to odd-numbered ones of the vertical structures VS arranged in the second direction D2, and a second bit line BL2 may be connected in common to even-numbered ones of the vertical structures VS arranged in the second direction D2.

FIG. 6B is a diagram illustrating an example condition of voltages for operations of a semiconductor memory device according to some implementations of the present disclosure.

In some implementations, a current path passing through the vertical channel in a program operation PGM and an erase operation ERS may be controlled by the word line WL. A current path passing through the vertical channel in a read operation READ may be controlled by the back-gate electrode BG.

Referring to FIGS. 1, 3, 4, 5, and 6B, in the program operation PGM, one cell string CSTR and one memory cell MCT may be selected. That is, a ground voltage (e.g., 0 V) may be applied to a selected bit line BL, a power voltage Vcc may be applied to a selected string selection line SSL(m), the ground voltage GND may be applied to an unselected string selection line SSL(m+1). A program voltage Vpgm (e.g., about +7 V) may be applied to a selected word line WL, and a pass voltage Vpass (e.g., about 4 V) may be applied to unselected word lines WL. In addition, the ground voltage (e.g., 0 V) may be applied to the common source line CSL. Furthermore, the back-gate electrodes BG and unselected bit lines BL may be in an electrically-floated state.

In the program operation PGM, a polarization state of the ferroelectric layer FEL in the selected memory cell MCT may be changed by a difference between the program voltage Vpgm applied to the word line WL and the voltage applied to the vertical channel VC. The difference between the program voltage Vpgm and the voltage applied to the vertical channel VC may be greater than the lowest level of a voltage required to change the polarization state of the ferroelectric layer FEL. As a result of the program operation, the polarization state of the ferroelectric layer FEL may be set to a first or second polarization state. In the first polarization state, positive charges in the ferroelectric layer FEL may be, for example, accumulated near the vertical channel VC. In the second polarization state, negative charges in the ferroelectric layer FEL may be accumulated near the vertical channel VC. That is, a memory cell in the first polarization state may have a lowered threshold voltage, and a memory cell in the second polarization state may have an increased threshold voltage.

The erase operation ERS on the memory cells may be performed on one or more memory blocks. For example, the ground voltage (e.g., 0 V) may be applied to the bit lines BL, which are connected to the cell strings in the memory block, and the back-gate electrodes BG and unselected one of the bit lines BL may be in an electrically-floated state.

An erase voltage Vers (e.g., −7 V) may be applied to a selected word line WL, and a pass voltage Vpass (e.g., about 4 V) may be applied to unselected word lines WL. The string selection lines SSL(m) may be in a floated state, and the ground voltage (e.g., 0 V) may be applied to the common source line CSL and ground selection lines GSL.

In the erase operation ERS, due to a difference between the program voltage Vers applied to the word line WL and the voltage applied to the vertical channel VC, the ferroelectric layer FEL may have the second polarization state.

Furthermore, in the read operation READ, one cell string and one memory cell may be selected, and data stored in the memory cell MCT may be read by measuring a current flowing through the vertical channel VC. For example, a bit line voltage VBL (e.g., about 0.7 V) may be applied to a selected one of the bit lines BL, and unselected ones of the bit lines BL may be in an electrically-floated state. The power voltage Vcc may be applied to a selected string selection line SSL(m), and the ground voltage (e.g., 0 V) may be applied to an unselected string selection line SSL(m+1). The ground voltage (e.g., 0 V) may be applied to the common source line CSL.

When all of the word lines WL are in an electrically-floated state, a read voltage (or sweep voltage) may be applied to a selected back-gate electrode BG. Here, the read voltage may be a voltage changing from a low level to a high level during the read operation READ. Furthermore, unselected ones of the back-gate electrodes BG and unselected ones of the bit lines BL may be in an electrically-floated state.

The control operations described with respect to FIG. 6B can, in some implementations, be applied to various memory devices described herein, such as the devices described with respect to FIGS. 1-6A and 7-34.

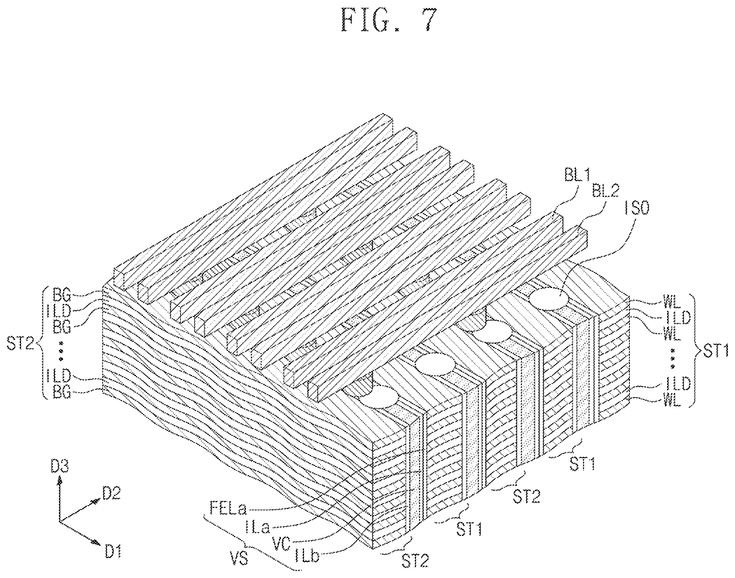

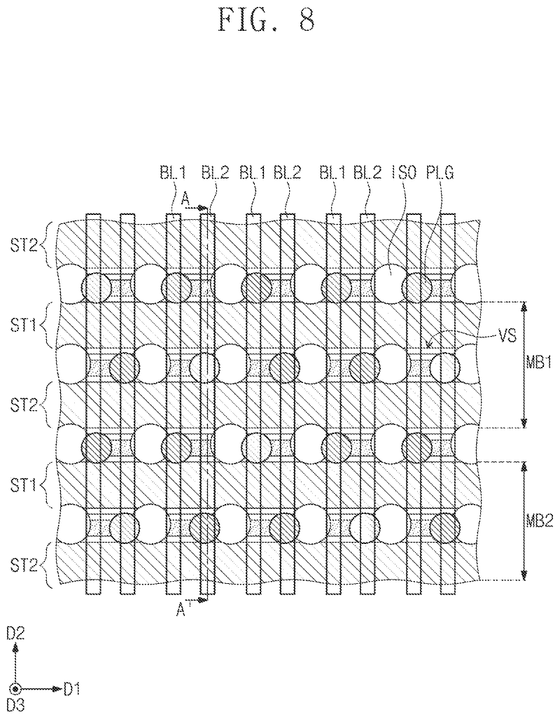

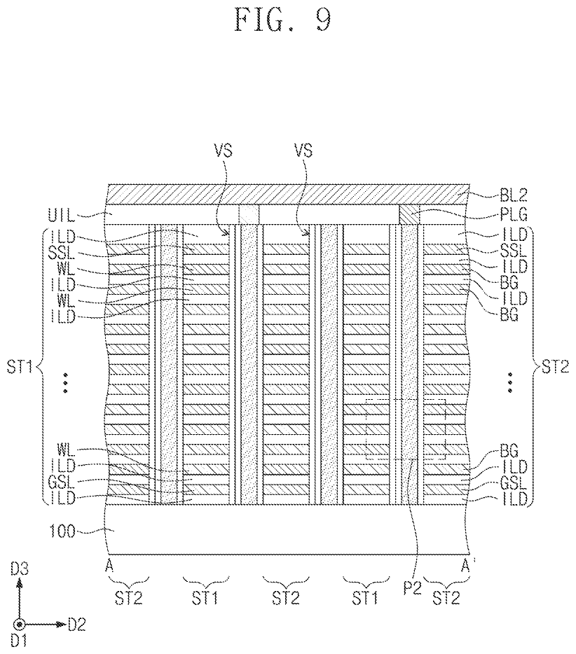

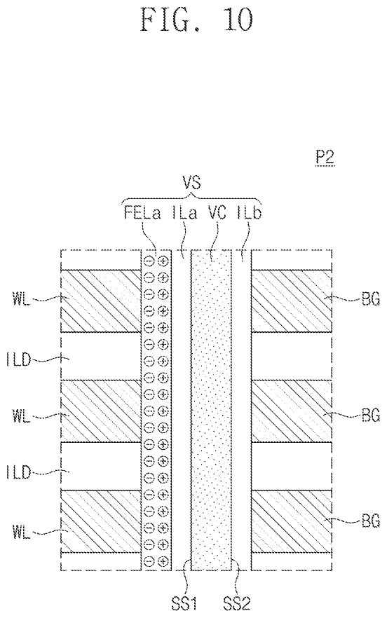

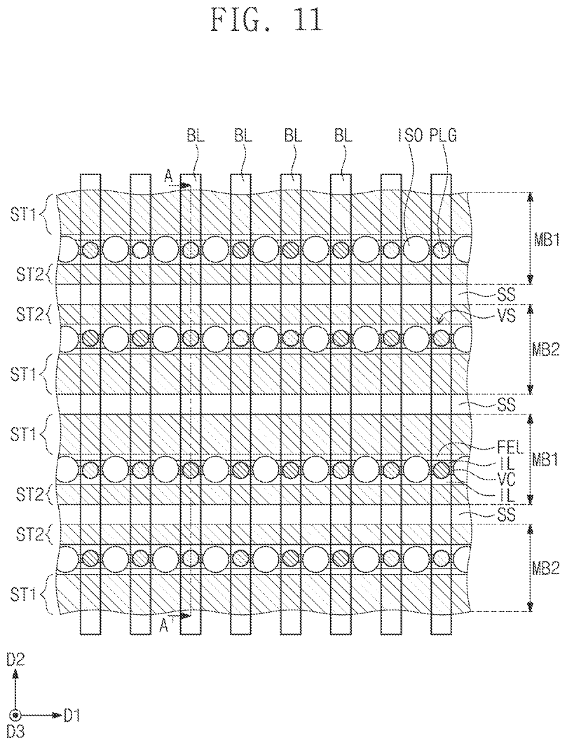

FIG. 7 is a perspective view illustrating a semiconductor memory device according to some implementations of the present disclosure. FIG. 8 is a plan view illustrating a semiconductor memory device according to some implementations of the present disclosure. FIG. 9 is a sectional view taken along line a A-A′ of FIG. 8. FIG. 10 is an enlarged sectional view illustrating a portion ‘P2’ of FIG. 9. The same technical features as the semiconductor memory device in the implementations of FIGS. 3, 4, and 5 described above will not be described in much further detail, for concise description.

Referring to FIGS. 7, 8, and 9, a semiconductor memory device may include the first and second stacks ST1 and ST2, which are alternately arranged in the second direction D2, and the vertical structures VS, which are disposed between adjacent ones of the first and second stacks ST1 and ST2. On the first and second side surfaces SS1 and SS2 of the vertical channel VC, each of the vertical structures VS may have an asymmetric dielectric structure. In detail, each of the first and second stacks ST1 and ST2 may have a first sidewall and a second sidewall opposite to the first sidewall. The first intermediate insulating layer ILa and the first ferroelectric layer FELa may be disposed between the vertical channel VC and the first sidewall of each of the first and second stacks ST1 and ST2. The second intermediate insulating layer ILb may be disposed between the vertical channel VC and the second sidewall of each of the first and second stacks ST1 and ST2.

In detail, referring to FIG. 10, the first intermediate insulating layer ILa and the first ferroelectric layer FELa may be disposed on the first side surface SS1 of the vertical channel VC, and the second intermediate insulating layer ILb may be disposed on the second side surface SS2 of the vertical channel VC. The second intermediate insulating layer ILb may be in direct contact with a side surface of the second stack ST2. For example, the second intermediate insulating layer ILb may be in direct contact with the back-gate electrodes BG. The first intermediate insulating layer ILa and the second intermediate insulating layer ILb may have substantially the same thickness and may be formed of or include the same insulating material.

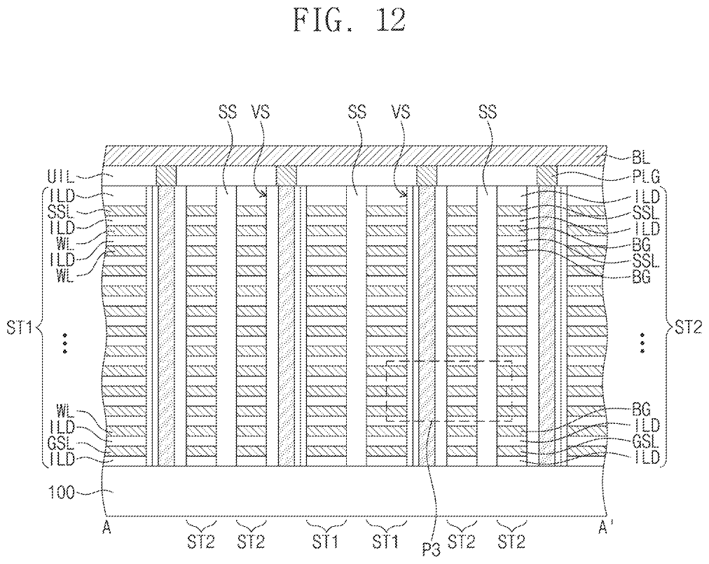

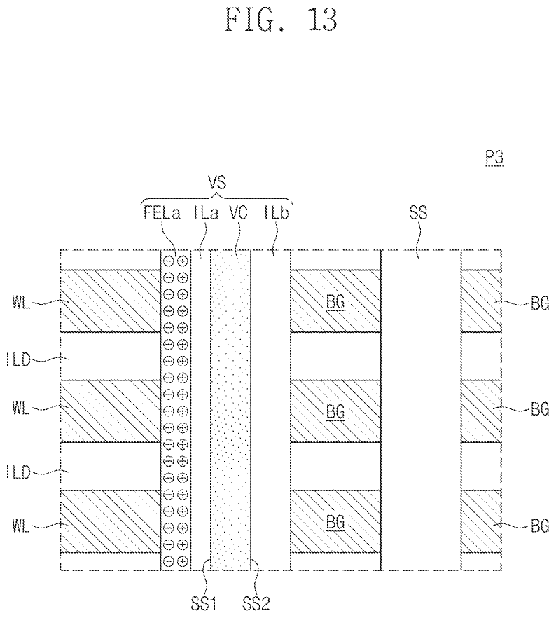

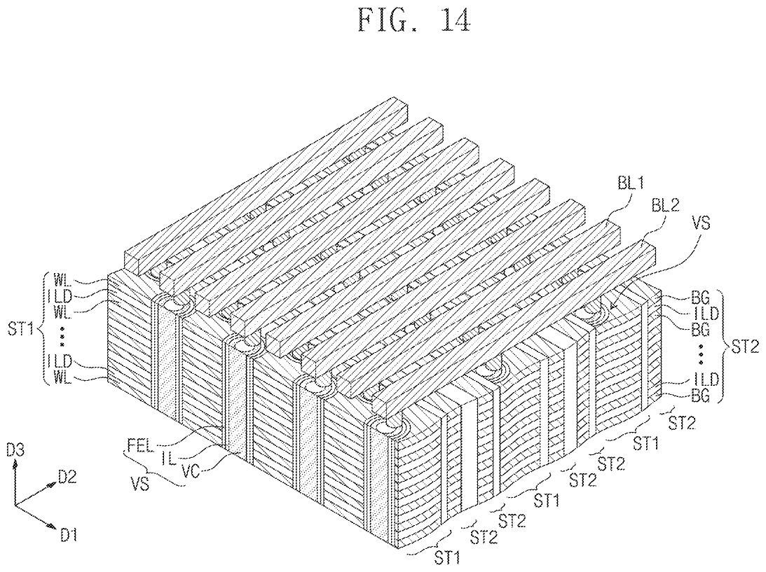

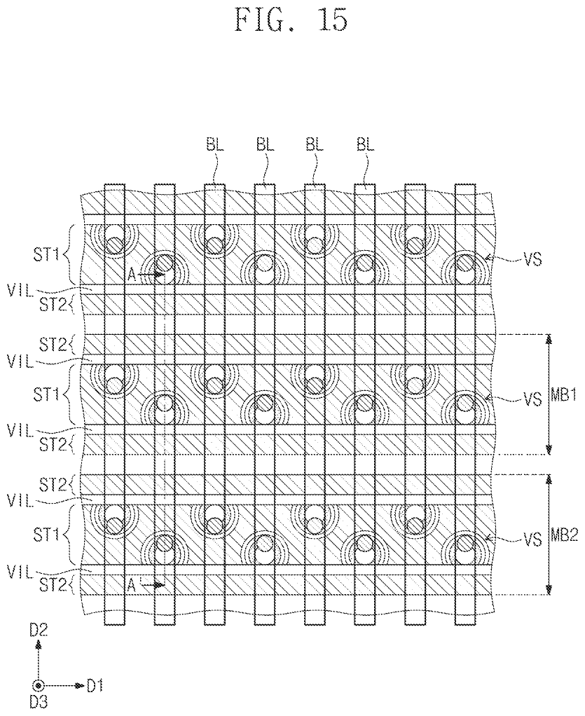

FIG. 11 is a plan view illustrating a semiconductor memory device according to some implementations of the present disclosure. FIG. 12 is a sectional view taken along a line A-A′ of FIG. 11. FIG. 13 is an enlarged sectional view illustrating a portion ‘P3’ of FIG. 12.

Referring to FIGS. 11, 12, and 13, a semiconductor memory device may include the first stacks ST1, the second stacks ST2, the vertical structures VS, the insulating isolation patterns ISO, and the bit lines BL. In addition, the semiconductor memory device may further include a pair of separation structures SS, which are extended in the first direction D1 and are parallel to each other.

As described above, the first stacks ST1 may include the word lines WL, which are vertically stacked on the substrate 100. As described above, the second stacks ST2 may include the back-gate electrodes BG, which are vertically stacked on the substrate 100.

In some implementations, between a pair of the separation structures SS, the first stack ST1 and the second stack ST2 may extend in the first direction D1 and parallel to each other, and here, the first and second stacks ST1 and ST2 may be arranged to have a mirror symmetry in the second direction D2. That is, a first separation structure, which is one of the separation structures SS, may be disposed between adjacent ones of the first stacks ST1, and a second separation structure, which is another of the separation structures SS, may be disposed between adjacent ones of the second stacks ST2.

Each of the separation structures SS may include an insulating layer, which is provided to cover a side surface of the first or second stack ST1 or ST2. Each of the separation structures SS may have a single- or multi-layered structure.

The separation structures SS may extend perpendicularly to the top surface of the substrate 100, and the separation structures SS may have top surfaces that are located at a level that is equal to or higher than top surfaces of the vertical structures VS.

Referring to FIG. 13, each of the vertical structures VS may include the vertical channel VC, the first ferroelectric layer FELa, and the first and second intermediate insulating layers ILa and ILb, as described above. Here, the first ferroelectric layer FELa may be disposed between the word lines WL and the first intermediate insulating layer ILa, and the first intermediate insulating layer ILa may be disposed between the first ferroelectric layer FELa and the first side surface SS1 of the vertical channel VC. The second intermediate insulating layer ILb may be disposed between the back-gate electrodes BGa and the second side surface SS2 of the vertical channel VC. Here, the second intermediate insulating layer ILb may be in direct contact with side surfaces of the back-gate electrodes BGa. A thickness of the second intermediate insulating layer ILb may be larger than a thickness of the first intermediate insulating layer ILa. In the case where, as described above, the second intermediate insulating layer ILb is thicker than the first intermediate insulating layer ILa, during operations of the semiconductor memory device, a capacitance between the vertical channel VC and the word line WL may be different from a capacitance between the vertical channel VC and the back-gate electrode BG; that is, there may be asymmetry in capacitance in the memory cell.

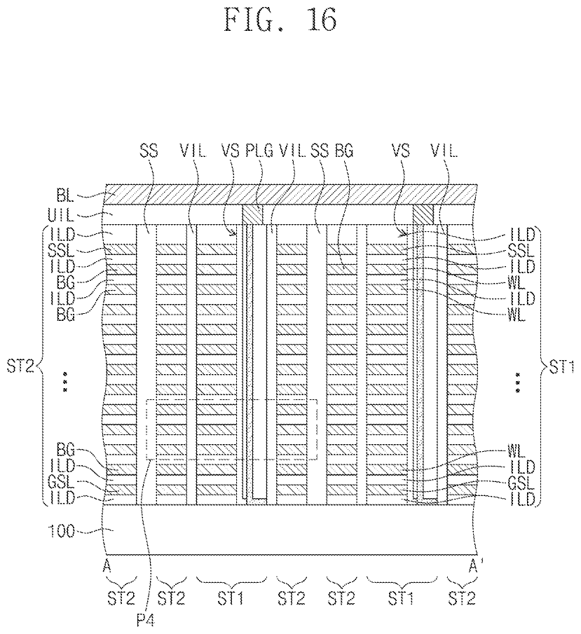

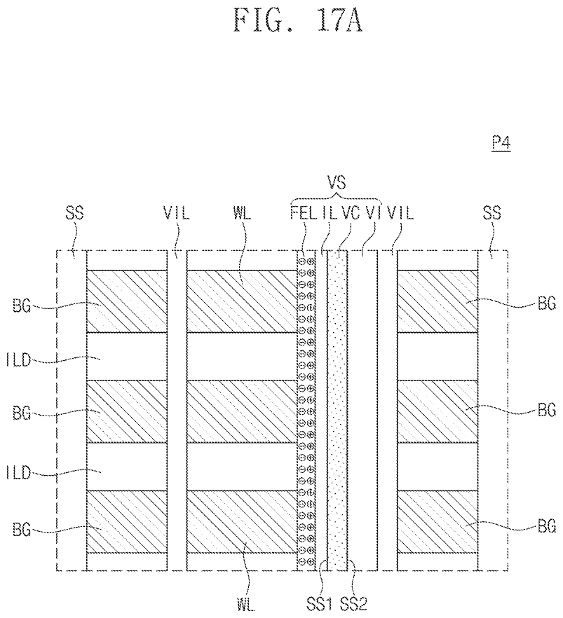

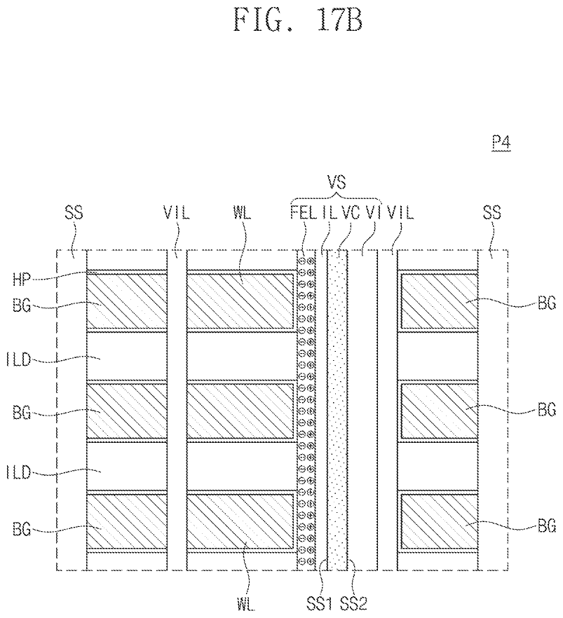

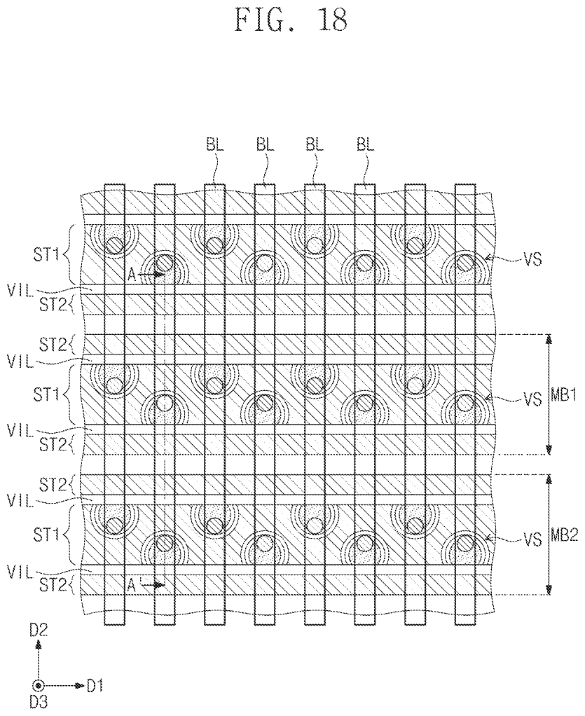

FIG. 14 is a perspective view illustrating a semiconductor memory device according to some implementations of the present disclosure. FIG. 15 is a plan view illustrating a semiconductor memory device according to some implementations of the present disclosure. FIG. 16 is a sectional view taken along a line A-A′ of FIG. 15. FIGS. 17A and 17B are enlarged sectional views illustrating a portion ‘P4’ of FIG. 16.

Referring to FIGS. 14, 15, and 16, a semiconductor memory device may include the first memory block MB1 and the second memory block MB2, and each of the first and second memory blocks MB1 and MB2 may include the first stack ST1, a pair of the second stacks ST2, the vertical structures VS, and vertical insulating layers VIL.

The semiconductor memory device may further include a pair of the separation structures SS, which are extended in the first direction D1 and parallel to each other, and the first and second memory blocks MB1 and MB2 may be respectively disposed between the pair of the separation structures SS.

As described above, the first and second stacks ST1 and ST2 may extend in the first direction D1, and as shown here, the first stack ST1 may be disposed between a pair of the second stacks ST2. The vertical insulating layers VIL may extend in the first direction D1, between the first and second stacks ST1 and ST2. The vertical insulating layers VIL may extend perpendicular to the top surface of the substrate 100 and may cover both side surfaces of the first stack ST1 and side surfaces of the second stacks ST2.

Each of the first stacks ST1 may include the word lines WL, which are stacked on the substrate 100, and when viewed in a plan view, it may extend in the first direction D1 and may enclose the vertical structures VS.

Each of the second stacks ST2 may include the back-gate electrodes BG, which are stacked on the substrate 100, and may have a uniform width. A width of each of the second stacks ST2 may be smaller than a width of each first stack ST1.

In some implementations, the vertical structures VS may be provided to penetrate the first stacks ST1. The vertical structures VS may be arranged in a specific direction (e.g., along a common line) or may be arranged in a zigzag shape, when viewed in a plan view. For example, FIG. 15 illustrates vertical structures arranged in a zigzag shape in direction D1, where the positions of the vertical structures in direction D2, among vertical structures that penetrate a given first stack ST1, alternate for alternating vertical structures along the direction D1. As a distance from the substrate 100 increases, a width or diameter of the vertical structure VS may increase. For example, the vertical structure VS may have a side surface that is inclined at an angle to the top surface of the substrate 100.

Each of the vertical structures VS may have a circular segment (e.g., semi-circular) section (e.g., in a plan view). Each of the vertical structures VS may have a flat first side surface and a rounded second side surface, and the first side surfaces of the vertical structures VS may be aligned to both side surfaces of the first stack ST1. Both side surfaces of the vertical structures VS may be in contact with the vertical insulating layer VIL.

In more detail, referring to FIG. 17A, each of the vertical structures VS may include the vertical channel VC, the ferroelectric layer FEL, an intermediate insulating layer IL, and a vertical insulating layer VI.

The vertical channel VC may have an L-shaped section and may be in contact with the substrate 100. For example, the vertical channel VC may have a first portion that extends perpendicular to the top surface of the substrate 100, and a second portion that extends parallel to the top surface of the substrate 100, e.g., along the top surface of the substrate 100, the first portion and the second portion forming the L-shape. The second portion may be between the substrate 100 and the vertical insulating layer VI. The vertical insulating layer VI may be disposed on the vertical channel VC. The vertical insulating layer VI may have a circular segment (e.g., semi-circular) pillar shape. The vertical insulating layer VI may be formed of or include an insulating material (e.g., silicon oxide).

The intermediate insulating layer IL may be provided to enclose the rounded second side surface of the vertical channel VC, and the ferroelectric layer FEL may be provided to enclose the intermediate insulating layer IL.

In some implementations, as shown in FIG. 17B, a horizontal insulating pattern HP may extend from regions on side surfaces of the word lines and back-gate electrodes WL and BG and regions on top and bottom surfaces thereof. For example, the horizontal insulating pattern HP may be disposed between the top and bottom surfaces of each word line WL and the insulating layers ILD and between the top and bottom surfaces of the back-gate electrode BG and the insulating layers ILD. The horizontal insulating pattern HP may be formed of or include at least one of high-k dielectric materials, silicon oxide, silicon nitride, or silicon oxynitride and may have a single or multi-layered structured. Although shown in reference to FIG. 17B, the horizontal insulating patterns HP may be included in other implementations described herein, e.g., the implementations of FIGS. 10, 13, 20, and 23.

Referring back to FIGS. 14, 15, and 16, the upper insulating layer UIL may be disposed on the first and second stacks ST1 and ST2, and the contact plugs PLG may be provided to penetrate the upper insulating layer UIL and may be respectively coupled to the vertical channels VC.

The bit lines BL may be provided on the upper insulating layer UIL to cross the first and second stacks ST1 and ST2 and to extend in the second direction D2, and each of the bit lines BL may be connected to the vertical channels VC through the contact plugs PLG.

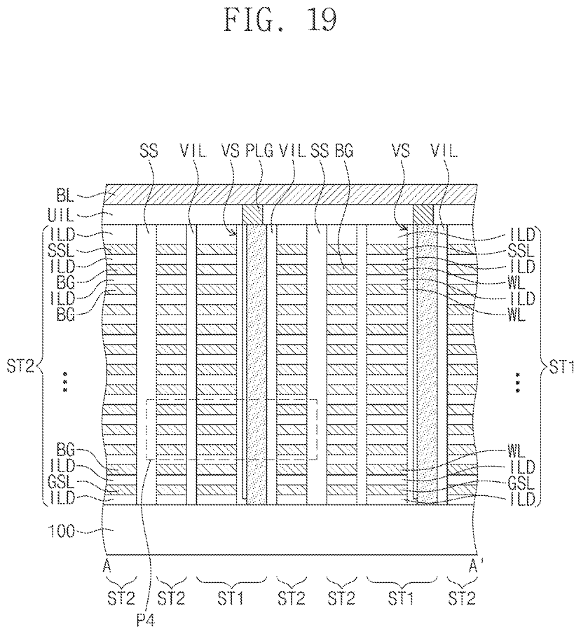

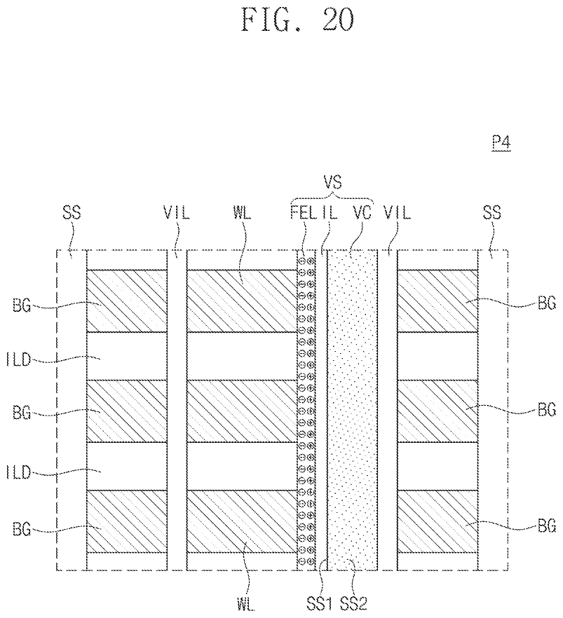

FIG. 18 is a plan view illustrating a semiconductor memory device according to some implementations of the present disclosure. FIG. 19 is a sectional view taken along a line A-A′ of FIG. 18. FIG. 20 is an enlarged sectional view illustrating a portion ‘P5’ of FIG. 19. The same technical features as the semiconductor memory device in the implementations of FIGS. 14, 15, and 16 described above will not be described in much further detail, for concise description.

Referring to FIGS. 18, 19, and 20, a semiconductor memory device may include the first stacks ST1, the second stacks ST2, the vertical structures VS, the vertical insulating layer VIL, the separation structures SS, and the bit lines BL.

Each of the vertical structures VS may include the vertical channel VC, the ferroelectric layer FEL, and the intermediate insulating layer IL. As shown in this example, the vertical channel VC may have a shape of a circular segment (e.g., semi-circular) pillar, and a side surface of the vertical channel VC may be in contact with the vertical insulating layer VIL.

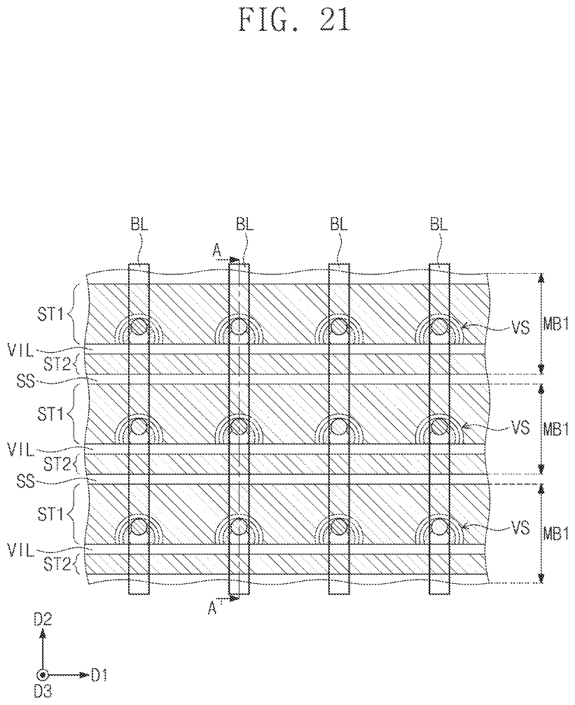

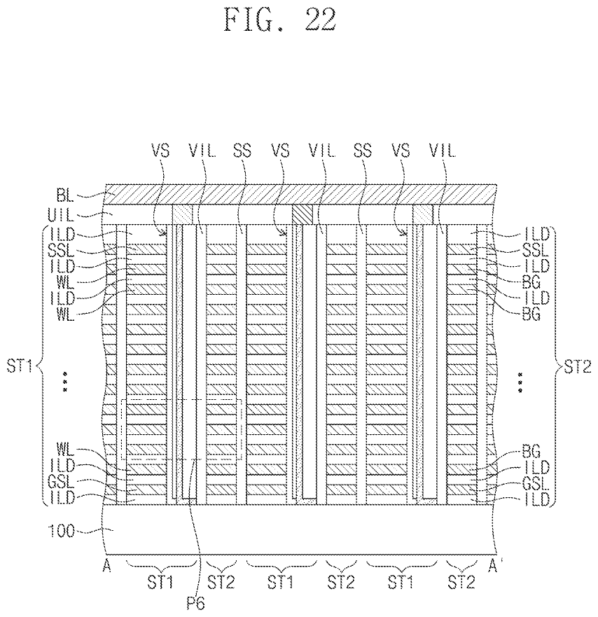

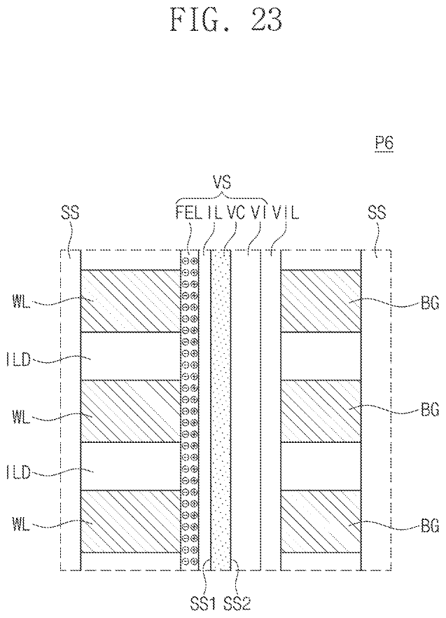

FIG. 21 is a plan view illustrating a semiconductor memory device according to some implementations of the present disclosure. FIG. 22 is a sectional view taken along a line A-A′ of FIG. 21. FIG. 23 is an enlarged sectional view illustrating a portion ‘P6’ of FIG. 22.

Referring to FIGS. 21, 22, and 23, a semiconductor memory device may include a plurality of memory blocks MB1, and each of the memory blocks MB1 may include the first stack ST1, the second stack ST2, the vertical structures VS, the vertical insulating layers VIL, the separation structures SS, and the bit lines BL.

Each of the first and second stacks ST1 and ST2 may have a first side surface and a second side surface, which are opposite to each other in the second direction D2. In some implementations, a width of the first stack ST1 may be larger than a width of the second stack ST2. The second stacks ST2 may be respectively disposed between adjacent ones of the first stacks ST1.

The vertical insulating layer VIL may be disposed on the first side surface of the first stack ST1, and the separation structure SS may be disposed on the second side surface of the first stack ST1. Similarly, the second stack ST2 may be disposed between the vertical insulating layer VIL and the separation structure.

The vertical insulating layer VIL may be disposed between the first side surfaces of the vertical structures VS and the second stack ST2, and the vertical insulating layer VIL may extend in the first direction D1. The vertical insulating layer VIL may cover the first side surface of the first stack ST1 and the second side surface of the second stack ST2.

The separation structure SS may be disposed between the first side surface of the second stack ST2 and the second side surface of the first stack ST1. For example, the separation structure SS may extend in the first direction D1, between the first stack ST1 and the second stack ST2.

The vertical structures VS may be arranged to be spaced apart from each other by a specific distance in the first direction D1. Each of the vertical structures VS may have a circular segment (e.g., semi-circular section), as previously described with reference to FIGS. 15, 16, and 17. Each of the vertical structures VS may have a flat first side surface and a rounded second side surface, and the first side surfaces of the vertical structures VS may be aligned to the first side surface of the first stack ST1. The first side surfaces of the vertical structures VS may be in contact with the vertical insulating layer VIL.

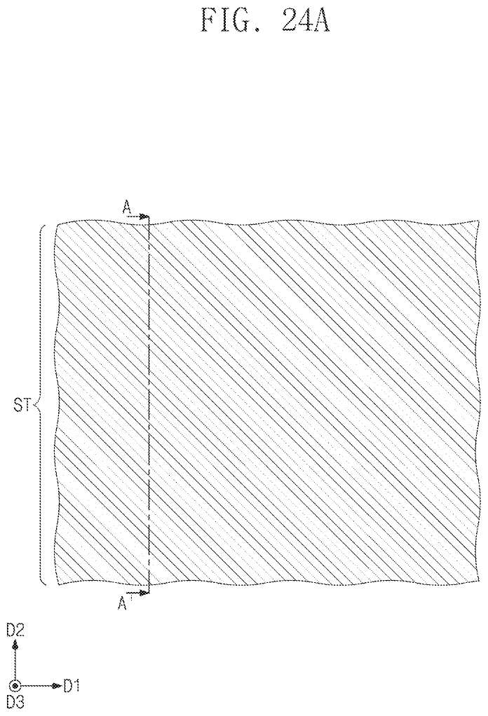

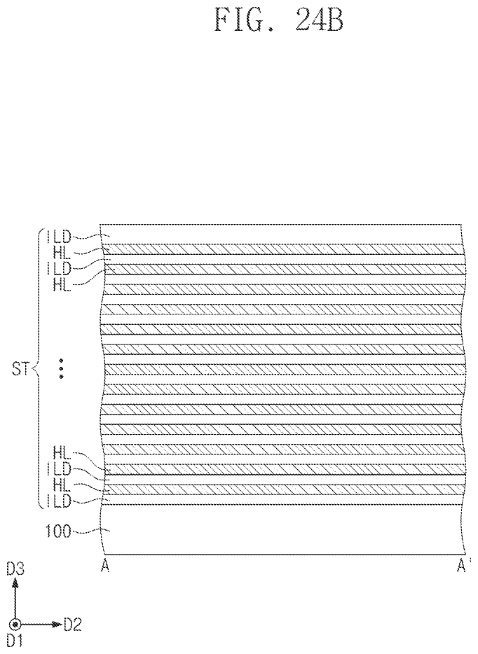

FIGS. 24A to 28A are plan views illustrating a method of fabricating a semiconductor memory device according to some implementations of the present disclosure. FIGS. 24B to 28B are sectional views which are taken along lines A-A′ of FIGS. 24A to 28A to illustrate a method of fabricating a semiconductor memory device according to some implementations of the present disclosure.

Referring to FIGS. 24A and 24B, a layered structure ST including horizontal layers HL and insulating layers ILD, which are vertically and alternately stacked on the substrate 100, may be formed. Here, the horizontal layers HL may be formed of or include at least one of conductive materials (e.g., doped polysilicon) or metallic materials (e.g., tungsten (W) and/or titanium (Ti)). In some implementations, the horizontal layers HL may be formed of or include an insulating material having an etch selectivity with respect to the insulating layers ILD. In this case, a step of replacing the horizontal layers HL with a conductive material may be performed in a subsequent process.

The horizontal layers HL and the insulating layers ILD may be deposited using one or more of thermal chemical vapor deposition (thermal CVD), plasma-enhanced CVD, physical CVD, or atomic layer deposition (ALD) techniques.

In the layered structure ST, the horizontal layers HL may have the same thickness. In some implementations, the lowermost and uppermost ones of the horizontal layers HL may be thicker than the others therebetween. In addition, the insulating layers ILD may have the same thickness, but in some implementations, at least one of the insulating layers ILD may have a thickness different from the others.

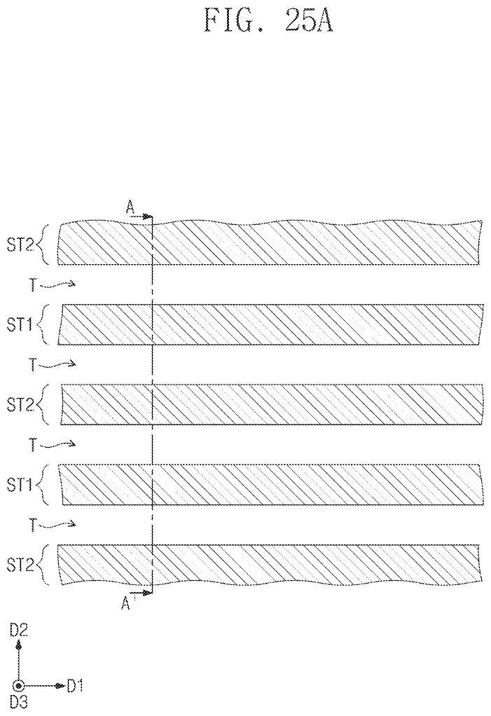

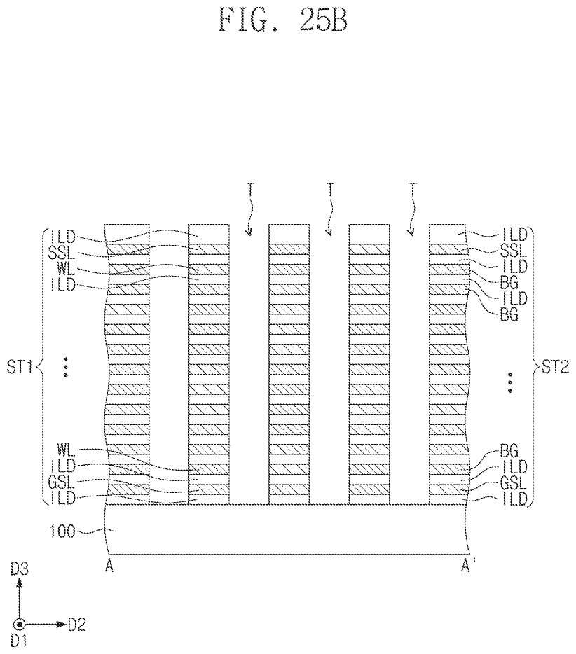

Referring to FIGS. 25A and 25B, the layered structure ST may be patterned to form trenches T exposing side surfaces of the horizontal and insulating layers HL and ILD.

The formation of the trenches T may include forming a mask pattern (not shown) on the layered structure ST to define planar positions and shapes of the trenches T and anisotropically etching the layered structure ST using the mask pattern (not shown) as an etch mask. As a result of the formation of the trenches T, the layered structure ST may be divided into the first and second stacks ST1 and ST2, which are provided in the form of a line.

When viewed in a plan view, the trenches T may be a line-shaped or rectangular empty region, which is extended in the first direction D1, and in some implementations, the trenches T may be formed to have a vertical depth large enough to expose the top surface of the substrate 100. In the case where the step of forming the trenches T is performed in an over-etch manner, the top surface of the substrate 100 exposed by the trenches T may be recessed by a specific depth. In addition, the trenches T may have an inclined side surface, even when the etching process is performed in an anisotropic manner.

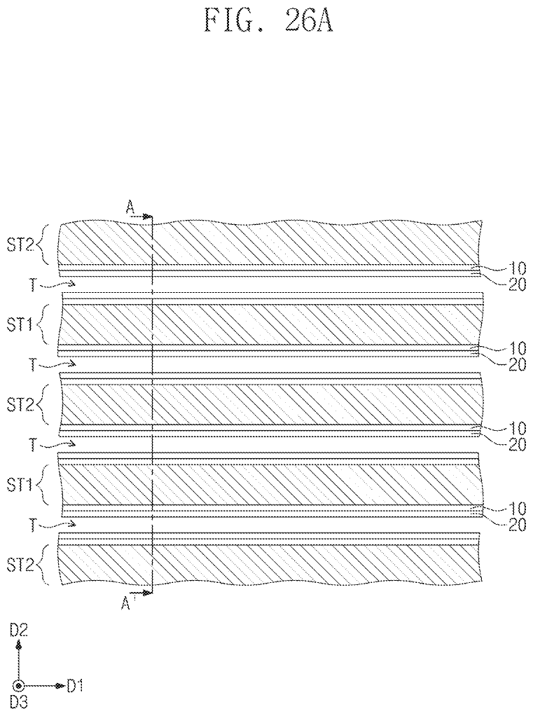

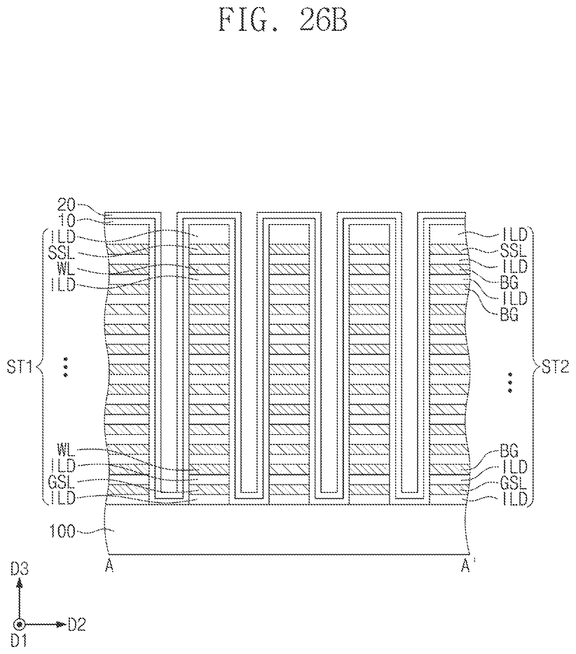

Referring to FIGS. 26A and 26B, a data storage layer 10 and an intermediate insulating layer 20 may be sequentially deposited to conformally cover inner surfaces of the trenches T. A sum of thicknesses of the data storage layer 10 and the intermediate insulating layer 20 may be smaller than half of a width of the trench T.

The data storage layer 10 and the intermediate insulating layer 20 may be deposited using one or more of thermal chemical vapor deposition (CVD), plasma-enhanced CVD, physical CVD, or atomic layer deposition (ALD) processes.

The data storage layer 10 may be formed of or include a ferroelectric material. For example, the data storage layer 10 may be formed of or include at least one of hafnium-containing dielectric materials. For example, the ferroelectric layer FEL may be formed of or include at least one of HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂.

The intermediate insulating layer 20 may be formed by depositing a non-ferroelectric material (e.g., silicon oxide).

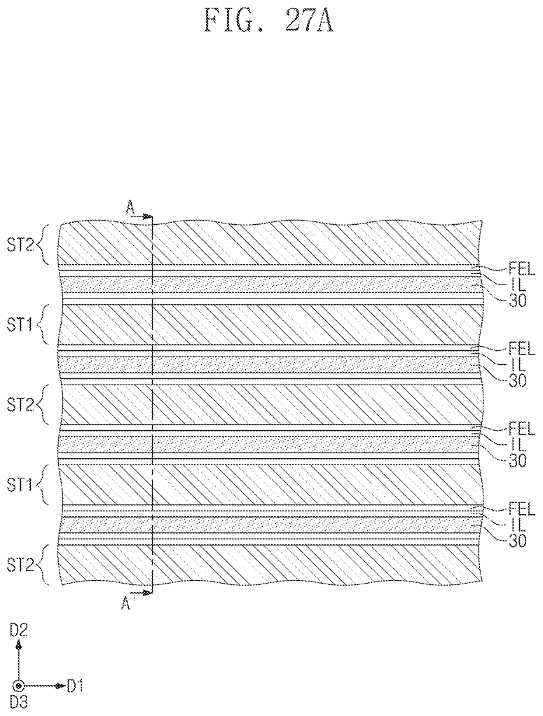

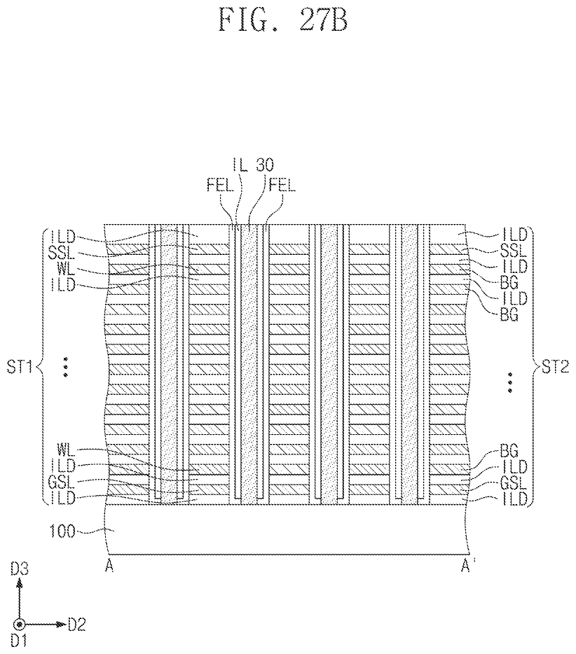

Referring to FIGS. 27A and 27B, an anisotropic etching process may be performed on the data storage layer 10 and the intermediate insulating layer 20 to expose the top surface of the substrate 100 near the bottom of the trench T. Thus, the ferroelectric layer FEL and an intermediate insulating pattern IL may be sequentially formed on opposite side surfaces of each trench T. The ferroelectric layer FEL and the intermediate insulating pattern IL may extend in the first direction D1 or along the side surfaces of the trenches T.

Next, a channel layer 30 may be formed to fill the trenches T, in which the ferroelectric layer FEL and the intermediate insulating pattern IL are formed.

The channel layer 30 may be a poly silicon layer, which is formed by one of atomic layer deposition (ALD) or chemical vapor deposition (CVD) techniques. The channel layer 30 in the trench T may extend in the first direction D1.

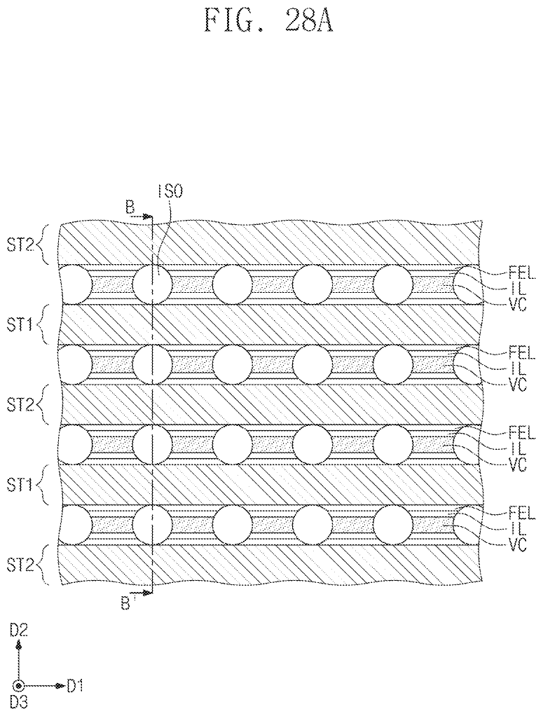

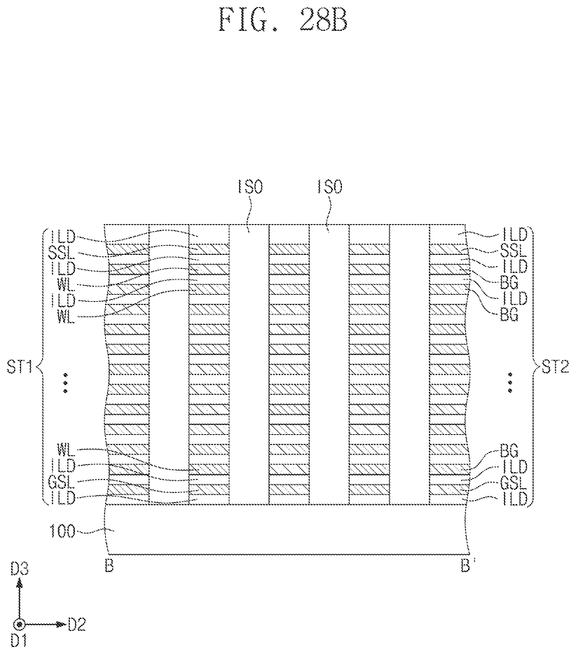

Referring to FIGS. 28A and 28B, openings may be formed between the first and second stacks to penetrate the channel layer 30, and as a result, the vertical channels VC, which are spaced apart from each other in the first direction D1, may be formed.

The formation of the openings may include forming a mask pattern (not shown) to have openings exposing portions of the channel layer 30 and anisotropically etching the channel layer 30 using the mask pattern as an etch mask. The openings may be formed to expose the top surface of the substrate 100, and the top surface of the substrate 100 below the openings OP may be partially recessed, due to an over-etching in the anisotropic etching step.

When the openings OP are formed, the ferroelectric layer FEL and the intermediate insulating pattern IL may be spaced apart from each other in the first direction D1, and side surfaces of the first and second stacks ST1 and ST2 may be exposed.

Next, the insulating isolation patterns ISO may be formed to fill the openings OP, respectively.

The insulating isolation pattern ISO may be formed of or include at least one of insulating materials, which are formed by spin-on-glass (SOG) techniques, silicon oxide materials, or silicon oxynitride materials. The formation of the insulating isolation patterns ISO may include depositing an insulating isolation layer to fill the openings OP and planarizing the insulating isolation layer.

Thereafter, as shown in FIGS. 4 and 5, the upper insulating layer UIL may be formed on the first and second stacks ST1 and ST2, and the bit lines BL, which are extended in the second direction D2, may be formed on the upper insulating layer UIL.

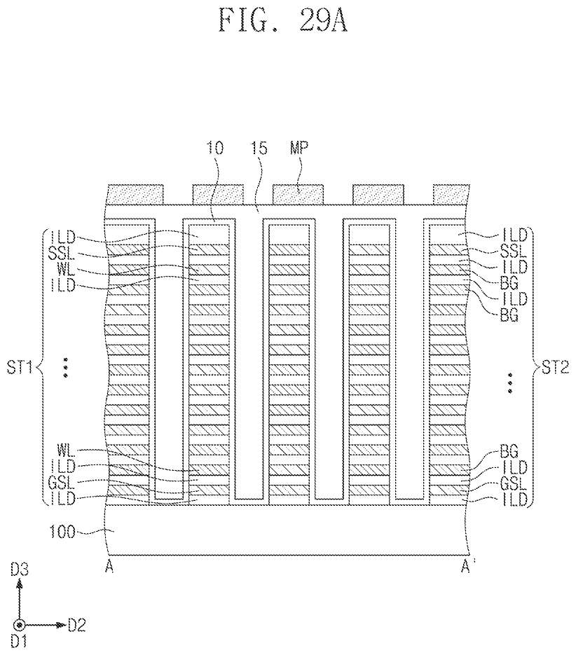

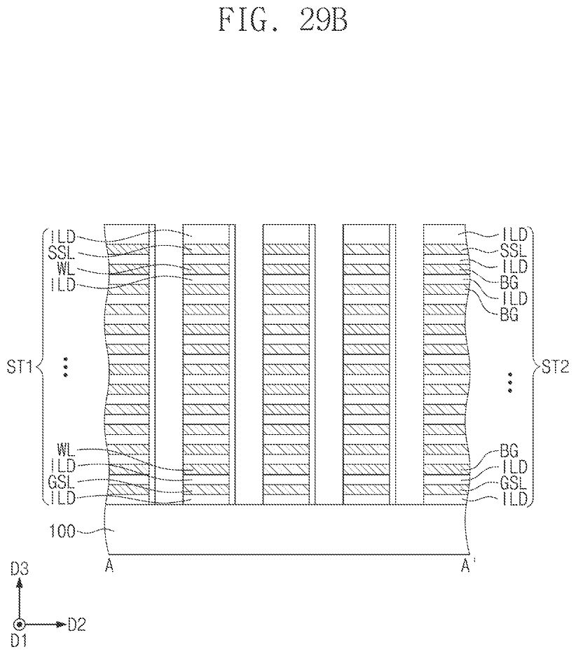

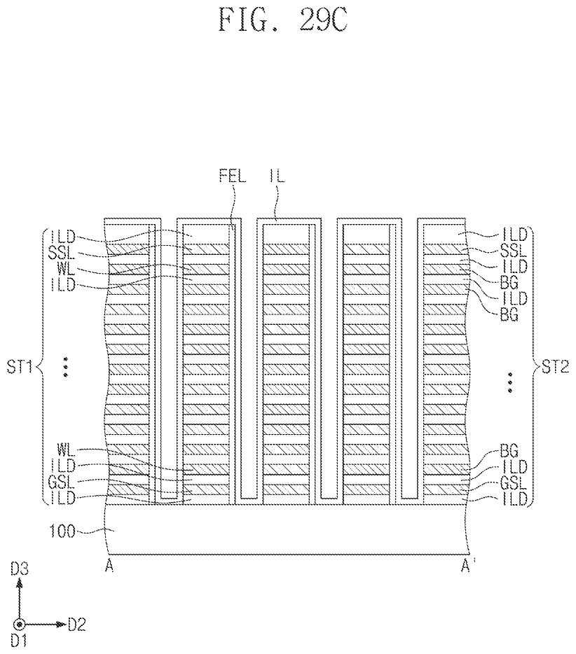

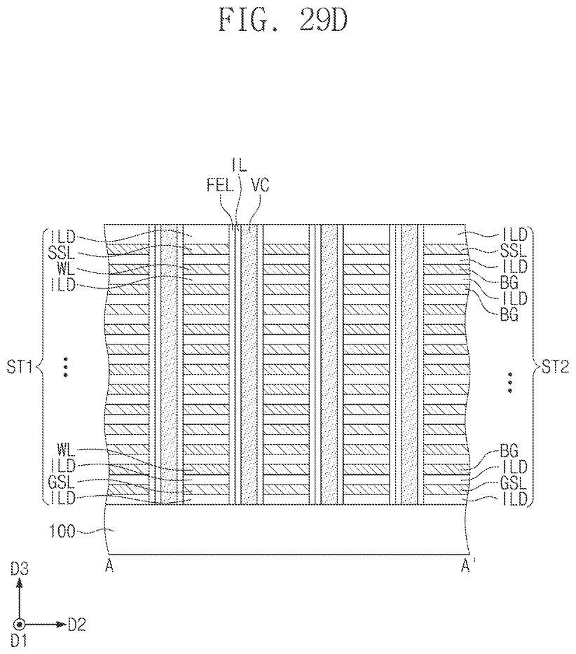

FIGS. 29A to 29D are sectional views which are taken along the line A-A′ of FIG. 8 to illustrate a method of fabricating a semiconductor memory device according to some implementations of the present disclosure.

Referring to FIGS. 8 and 29A, as described with reference to FIG. 25B, after the forming of the trenches T separating the first and second stacks ST1 and ST2 from each other, the data storage layer 10 may be formed to conformally cover inner surfaces of the trenches T. The data storage layer 10 may be formed by depositing a ferroelectric material to have a thickness smaller than half of a width of the trench T, as previously described with reference to FIG. 26B.

After the deposition of the data storage layer 10, a sacrificial layer 15 may be formed to fill the trenches T. The sacrificial layer 15 may be formed of or include a material having an etch selectivity with respect to the data storage layer 10.

Next, a mask pattern MP having line-shaped openings may be formed on the sacrificial layer 15. The mask pattern MP may be formed on a position corresponding to side surfaces of the trenches T, and the openings of the mask pattern MP may be formed on positions corresponding to opposite side surfaces of the trenches T.

Referring to FIGS. 8 and 29B, an anisotropic etching process using the mask pattern MP as an etch mask may be performed on the sacrificial layer 15 and the data storage layer 10. Thus, a portion of the ferroelectric layer may be left on the side surfaces of the trenches T to form the ferroelectric layer FEL, and opposite side surfaces of the trenches T may be exposed. For example, side surfaces of the first and second stacks ST1 and ST2 may be exposed.

Referring to FIGS. 8 and 29C, the intermediate insulating layer IL may be deposited to cover the trenches, in which the ferroelectric layer FEL is formed, with a uniform thickness. The intermediate insulating layer IL may be formed by depositing a non-ferroelectric material (e.g., silicon oxide).

Referring to FIGS. 8 and 29D, an anisotropic etching process may be performed on the intermediate insulating layer 20 to form the intermediate insulating pattern IL on a side surface of the ferroelectric layer FEL and side surfaces of the first and second stacks ST1 and ST2. In addition, when the intermediate insulating pattern IL is formed, the top surface of the substrate 100 below the trenches T may be exposed.

Next, the channel layer 30 may be formed to fill the trenches T, in which the ferroelectric layer FEL and the intermediate insulating pattern IL are formed.

Although the process of FIGS. 24A-29D is illustrated as forming a structure as shown in FIG. 8, it will be understood that similar processes can be used to form the other structures described herein.

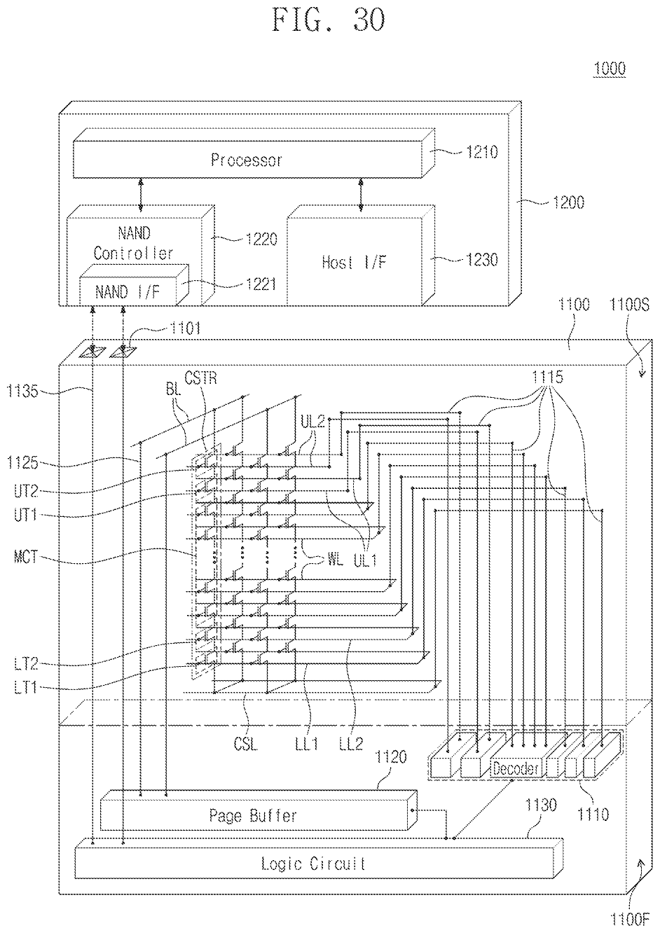

FIG. 30 is a schematic diagram schematically illustrating an electronic system including a semiconductor memory device according to some implementations of the present disclosure.

Referring to FIG. 30, an electronic system 1000 according to some implementations of the present disclosure may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided. In some implementations, the semiconductor device 1100 is a ferroelectric storage device, e.g., any of the ferroelectric storage devices described with respect to FIGS. 1-29D.

The semiconductor device 1100 may be a nonvolatile memory device (e.g., a NAND FLASH memory device). The semiconductor device 1100 may include a first structure 1100F and a second structure 1100S on the first structure 1100F. In some implementations, the first structure 1100F may be disposed beside the second structure 1100S.

The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cells MCT disposed between the lower transistors LT1 and LT2 and the upper transistors UT1 and UT2. The number of the lower transistors LT1 and LT2 and the number of the upper transistors UT1 and UT2 may be variously changed, according to implementations.

In some implementations, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cells MCT, and the gate upper lines UL1 and UL2 may be respectively used as gate electrodes of the upper transistors UT1 and UT2.

In some implementations, the memory cells MCT of each memory cell string CSTR may be controlled by a back-gate line.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may be configured to perform a control operation on at least one selected from the memory cells MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

Although not shown, the first structure 1100F may include a voltage generator (not shown). The voltage generator may generate a program voltage, a read voltage, a pass voltage, a verification voltage, and so forth, which are needed to operate the memory cell strings CSTR. Here, the program voltage may be a relatively high voltage (e.g., 20V to 40V), compared with the read voltage, the pass voltage, and the verification voltage.

In some implementations, the first structure 1100F may include high voltage transistors and low voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a program operation). The page buffer 1120 may also include high-voltage transistors which can stand the high voltage.

The controller 1200 may include a processor 1210, a NAND controller 1220, and a host interface 1230. In some implementations, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and receive control commands, which are used to control the semiconductor device 1100, and data, which will be written in or read from the memory cells MCT of the semiconductor device 1100. The host interface 1230 may be configured to allow for communication between the electronic system 1000 and an external host. When a control command is received from the external host through the host interface 1230, the processor 1210 may control the semiconductor device 1100 in response to the control command.

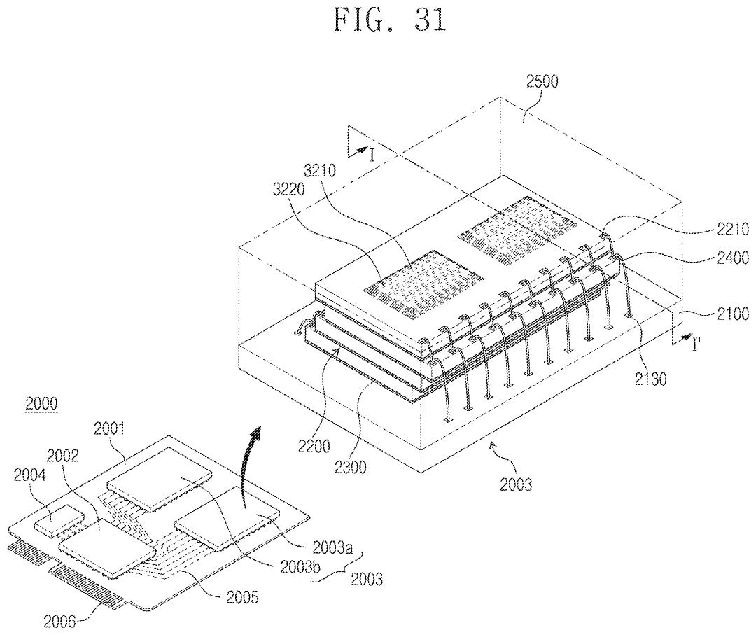

FIG. 31 is a perspective view schematically illustrating an electronic system including a semiconductor memory device according to some implementations of the present disclosure.

Referring to FIG. 31, an electronic system 2000 according to some implementations of the present disclosure may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 by interconnection patterns 2005, which are formed in the main substrate 2001.

The main substrate 2001 may include a connector 2006, which includes a plurality of pins coupled to an external host. In the connector 2006, the number and arrangement of the pins may be changed depending on a communication interface between the electronic system 2000 and the external host. In some implementations, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In some implementations, the electronic system 2000 may be driven by a power, which is supplied from the external host through the connector 2006. The electronic system 2000 may further include a power management integrated circuit (PMIC) that is configured to distribute a power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and an external host. In some implementations, the DRAM 2004 in the electronic system 2000 may serve as a cache memory and may be used as a storage space, which is configured to store data temporarily during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 30. Each of the semiconductor chips 2200 may include stacks 3210 and vertical structures 3220. Each of the semiconductor chips 2200 may include a semiconductor device, which will be described below, according to some implementations of the present disclosure.

In some implementations, the connection structure 2400 may be a bonding wire, which is provided to electrically connect the input/output pad 2210 to the upper pads 2130. Thus, in each of the first and second semiconductor packages 2003a and 2003b, the semiconductor chips 2200 may be electrically connected to each other in a bonding wire manner and may be electrically connected to the upper pads 2130 of the package substrate 2100. In some implementations, in each of the first and second semiconductor packages 2003a and 2003b, the semiconductor chips 2200 may be electrically connected to each other by a connection structure including through-silicon vias (TSVs), not by the connection structure 2400 provided in the form of bonding wires.

In some implementations, the controller 2002 and the semiconductor chips 2200 may be included in a single package. In some implementations, the controller 2002 and the semiconductor chips 2200 may be mounted on an additional interposer substrate different from the main substrate 2001 and may be connected to each other through interconnection lines, which are provided in the interposer substrate.

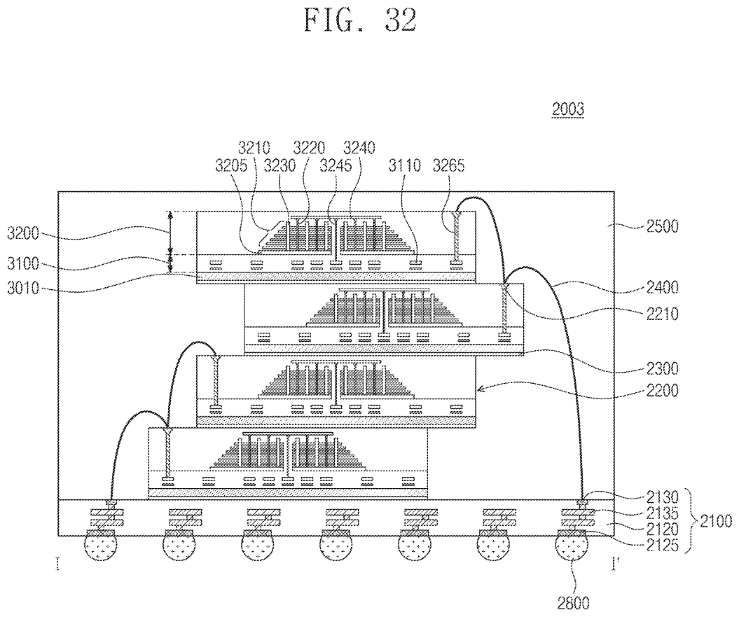

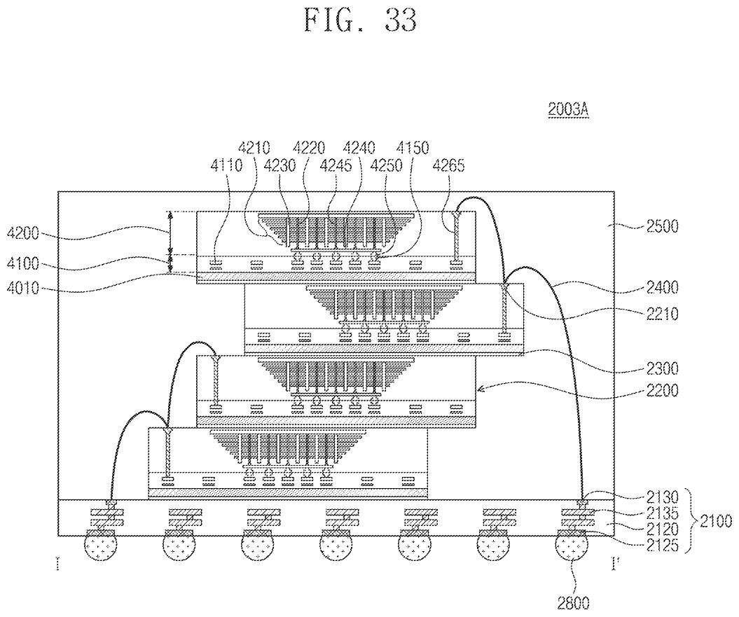

FIGS. 32 and 33 are schematic sectional views illustrating semiconductor packages according to implementations of the present disclosure. FIGS. 32 and 33 are sectional views taken along a line I-I′ of FIG. 31 and illustrate two different examples of the semiconductor package of FIG. 31.

Referring to FIG. 32, the package substrate 2100 of the semiconductor package 2003 may be a printed circuit board. The package substrate 2100 may include a package substrate body portion 2120, the upper pads 2130 (e.g., see FIG. 31), which are disposed on a top surface of the package substrate body portion 2120, lower pads 2125, which are disposed on or exposed through a bottom surface of the package substrate body portion 2120, and internal lines 2135, which are disposed in the package substrate body portion 2120 to electrically connect the package upper pads 2130 to the lower pads 2125. The package upper pads 2130 may be electrically connected to the connection structures 2400. The lower pads 2125 may be connected to the interconnection patterns 2005 of the main substrate 2001 of the electronic system 2000 shown in FIG. 31 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region including peripheral lines 3110. The second structure 3200 may include a source structure 3205, a stack 3210 on the source structure 3205, the vertical structures 3220 and separation structures 3230 penetrating the stack 3210, bit lines 3240 electrically connected to the vertical structures 3220, and cell contact plugs 3235 electrically connected to the word lines WL (e.g., see FIG. 30) of the stack 3210. Each of the first and second structures 3100 and 3200 and the semiconductor chips 2200 may further include separation structures to be described below.

Each of the semiconductor chips 2200 may include a penetration line 3245, which is electrically connected to the peripheral lines 3110 of the first structure 3100 and is extended into the second structure 3200. The penetration line 3245 may be disposed outside the stack 3210, and in some implementations, the penetration line 3245 may be provided to further penetrate the stack 3210. Each of the semiconductor chips 2200 may further include the input/output pad 2210 (e.g., see FIG. 31), which is electrically connected to the peripheral lines 3110 of the first structure 3100.

Referring to FIG. 33, in the semiconductor package 2003A, each of the semiconductor chips 2200a may include a semiconductor substrate 4010, a first structure 4100 on the semiconductor substrate 4010, and a second structure 4200, which is provided on the first structure 4100 and is bonded to the first structure 4100 in a wafer bonding manner.

The first structure 4100 may include a peripheral circuit region including a peripheral line 4110 and first junction structures 4150. The second structure 4200 may include a source structure 4205, a stack 4210 between the source structure 4205 and the first structure 4100, vertical structures 4220 and a separation structure 4230 penetrating the stack 4210, and second junction structures 4250, which are electrically and respectively connected to the vertical structures 4220 and the word lines WL (e.g., see FIG. 30) of the stack 4210. For example, the second junction structures 4250 may be electrically connected to the vertical structures 4220 and the word lines WL (e.g., see FIG. 30), respectively, through bit lines 4240 electrically connected to the vertical structures 4220 and cell contact plugs 4235 electrically connected to the word lines WL (e.g., see FIG. 30). The first junction structures 4150 of the first structure 4100 may be in contact with and bonded to the second junction structures 4250 of the second structure 4200. The bonded portions of the first junction structures 4150 and the second junction structures 4250 may be formed of or include, for example, copper Cu.

Each of the first and second structures 4100 and 4200 and the semiconductor chips 2200a may further include a source structure according to some implementations to be described below. Each of the semiconductor chips 2200a may further include the input/output pad 2210 (e.g., see FIG. 31), which is electrically connected to the peripheral lines 4110 of the first structure 4100.

The semiconductor chips 2200 of FIG. 32 and the semiconductor chips 2200a of FIG. 33 may be electrically connected to each other by the connection structures 2400, which are provided in the form of bonding wires. However, in some implementations, semiconductor chips provided in each semiconductor package (e.g., the semiconductor chips 2200 of FIG. 32 and the semiconductor chips 2200a of FIG. 33) may be electrically connected to each other through a connection structure including through-silicon vias (TSVs).

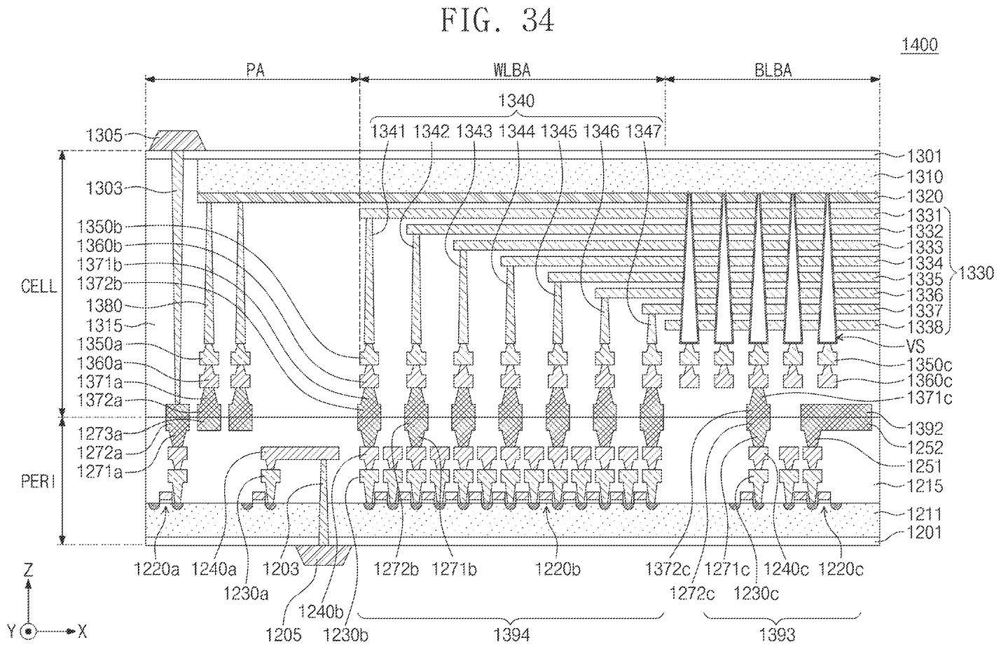

FIG. 34 is a sectional view illustrating a semiconductor memory device according to some implementations of the present disclosure.

Referring to FIG. 34, a memory device 1400 may have a chip-to-chip (C2C) structure. For the C2C structure, an upper chip including a cell array structure CELL may be fabricated on a first wafer, a lower chip including a peripheral circuit structure PERI may be fabricated on a second wafer different from the first wafer, and the upper chip and the lower chip may be connected to each other in a bonding manner. The bonding manner may mean a way of electrically connecting a bonding metal formed in the uppermost metal layer of the upper chip to a bonding metal formed in the uppermost metal layer of the lower chip. For example, in the case where the bonding metal is formed of copper (Cu), the bonding manner may be a Cu-to-Cu bonding manner, but in some implementations, aluminum (Al) or tungsten (W) may be used as the bonding metal. Each of the peripheral circuit structure PERI and the cell array structure CELL of the memory device 1400 may include an outer pad bonding region PA, a word line bonding region WLBA, and a bit line bonding region BLBA.

The peripheral circuit structure PERI may include a first substrate 1211, an interlayer insulating layer 1215, a plurality of circuit devices 1220a, 1220b, and 1220c formed on the first substrate 1211, first metal layers 1230a, 1230b, and 1230c connected to the circuit devices 1220a, 1220b, and 1220c, respectively, and second metal layers 1240a, 1240b, and 1240c formed on the first metal layers 1230a, 1230b, and 1230c. In some implementations, the first metal layers 1230a, 1230b, and 1230c may be formed of or include a material (e.g., tungsten) having relatively high electric resistivity, and the second metal layers 1240a, 1240b, and 1240c may be formed of or include a material (e.g., copper) having relatively low electric resistivity.

Although only the first metal layers 1230a, 1230b, and 1230c and the second metal layers 1240a, 1240b, and 1240c are illustrated and described in the present specification, the present disclosure is not limited thereto and at least one metal layer may be further formed on the second metal layers 1240a, 1240b, and 1240c. At least one of the additional metal layers, which are formed on the second metal layers 1240a, 1240b, and 1240c, may be formed of a material (e.g., aluminum), which has lower electric resistivity than the material (e.g., copper) of the second metal layers 1240a, 1240b, and 1240c.

The interlayer insulating layer 1215 may be disposed on the first substrate 1211 to cover the circuit devices 1220a, 1220b, and 1220c, the first metal layers 1230a, 1230b, and 1230c, and the second metal layers 1240a, 1240b, and 1240c and may be formed of or include at least one of insulating materials (e.g., silicon oxide and silicon nitride).

Lower bonding metals 1271b and 1272b may be formed on the second metal layer 1240b of the word line bonding region WLBA. In the word line bonding region WLBA, the lower bonding metals 1271b and 1272b of the peripheral circuit structure PERI may be electrically connected to upper bonding metals 1371b and 1372b of the cell array structure CELL in a bonding manner, and the lower bonding metals 1271b and 1272b and the upper bonding metals 1371b and 1372b may be formed of or include at least one of aluminum, copper, or tungsten.

The cell array structure CELL may include at least one memory block. The cell array structure CELL may include a second substrate 1310 and a common source line 1320. A plurality of word lines 1331-1338 (1330) may be stacked on the second substrate 1310 in a direction (e.g., a z-axis direction) that is perpendicular to a top surface of the second substrate 1310. String selection lines and a ground selection line may be respectively disposed on and below the word lines 1330; that is, the word lines 1330 may be disposed between the string selection lines and the ground selection line.

In the bit line bonding region BLBA, a vertical structure VS may be provided to extend in the direction (e.g., the z-axis direction) perpendicular to a top surface of the second substrate 1310 and to penetrate the word lines 1330, the string selection lines, and the ground selection line. The vertical structure VS may be configured to have substantially the same features as at least one of the vertical structures in the previous implementations. The vertical structure VS may include a ferroelectric layer and a vertical channel layer, and here, the channel layer may be electrically connected to a first metal layer 1350c and a second metal layer 1360c. For example, the first metal layer 1350c may be a bit line contact, and the second metal layer 1360c may be a bit line. In some implementations, the bit line 1360c may extend in a first direction (e.g., a y-axis direction) parallel to the top surface of the second substrate 1310.

In some implementations shown in FIG. 34, a region provided with the vertical structure VS and the bit line 1360c may be defined as the bit line bonding region BLBA. In the bit line bonding region BLBA, the bit lines 1360c may be electrically connected to the circuit devices 1220c, which are provided in the peripheral circuit structure PERI to constitute a page buffer 1393. As an example, the bit lines 1360c may be connected to the peripheral circuit structure PERI through upper bonding metals 1371c and 1372c, and the upper bonding metals 1371c and 1372c may be connected to lower bonding metals 1271c and 1272c, which are connected to the circuit devices 1220c of the page buffer 1393.

In the word line bonding region WLBA, the word lines 1330 may extend in a second direction (e.g., an x-axis direction), which is perpendicular to the first direction and is parallel to the top surface of the second substrate 1310, and may be connected to a plurality of cell contact plugs 1341-1347 (1340). The cell contact plugs 1340 may be connected to pads of the word lines 1330, which are extended to have different lengths from each other in the second direction. A first metal layer 1350b and a second metal layer 1360b may be sequentially connected to upper portions of the cell contact plugs 1340 connected to the word lines 1330. In the word line bonding region WLBA, the cell contact plugs 1340 may be connected to the peripheral circuit structure PERI through the upper bonding metals 1371b and 1372b of the cell array structure CELL and the lower bonding metals 1271b and 1272b of the peripheral circuit structure PERI.

In the peripheral circuit structure PERI, the cell contact plugs 1340 may be electrically connected to the circuit devices 1220b constituting a row decoder 1394. In some implementations, an operation voltage of the circuit devices 1220b constituting the row decoder 1394 may be different from an operation voltage of the circuit devices 1220c constituting the page buffer 1393. As an example, the operation voltage of the circuit devices 1220c constituting the page buffer 1393 may be higher than the operation voltage of the circuit devices 1220b constituting the row decoder 1394.

A common source line contact plug 1380 may be disposed in the outer pad bonding region PA. The common source line contact plug 1380 may be formed of a conductive material (e.g., metals, metal compounds, or polysilicon) and may be electrically connected to the common source line 1320. A first metal layer 1350a and a second metal layer 1360a may be sequentially stacked on the common source line contact plug 1380. A region, in which the common source line contact plug 1380, the first metal layer 1350a, and the second metal layer 1360a are provided, may be defined as the outer pad bonding region PA.

Input/output pads 1205 and 1305 may be disposed in the outer pad bonding region PA. Referring to FIG. 34, a lower insulating layer 1201 may be formed below the first substrate 1211 to cover the bottom surface of the first substrate 1211, and a first input/output pad 1205 may be formed on the lower insulating layer 1201. The first input/output pad 1205 may be connected to at least one of the circuit devices 1220a, 1220b, and 1220c of the peripheral circuit structure PERI through a first input/output contact plug 1203 and may be separated from the first substrate 1211 by the lower insulating layer 1201. In addition, a sidewall insulating layer (not shown) may be disposed between the first input/output contact plug 1203 and the first substrate 1211 to electrically separate the first input/output contact plug 1203 from the first substrate 1211.

Referring to FIG. 34, an upper insulating layer 1301 may be formed on the second substrate 1310 to cover the top surface of the second substrate 1310, and a second input/output pad 1305 may be disposed on the upper insulating layer 1301. The second input/output pad 1305 may be connected to at least one of the circuit devices 1220a, 1220b, and 1220c of the peripheral circuit structure PERI through a second input/output contact plug 1303. In some implementations, the second input/output pad 1305 may be electrically connected to the circuit device 1220a.

In some implementations, the second substrate 1310 and the common source line 1320 may not be disposed in a region provided with the second input/output contact plug 1303. In addition, the second input/output pad 1305 may not be overlapped with the word lines 1330 in the third direction (i.e., the z-axis direction). Referring to FIG. 34, the second input/output contact plug 1303 may be separated from the second substrate 1310 in a direction parallel to the top surface of the second substrate 1310, may penetrate an interlayer insulating layer 1315 of the cell array structure CELL, and may be connected to the second input/output pad 1305.

In some implementations, the first input/output pad 1205 and the second input/output pad 1305 may be selectively formed. As an example, the memory device 1400 may be configured to include only the first input/output pad 1205, which is provided on the first substrate 1211, or to include only the second input/output pad 1305, which is provided on the second substrate 1310. In some implementation, the memory device 1400 may be configured to include both of the first and second input/output pads 1205 and 1305.

A metal pattern, which is used as a dummy pattern, may be provided in the uppermost metal layer of the outer pad bonding region PA and the bit line bonding region BLBA, which are included in each of the cell array structure CELL and the peripheral circuit structure PERI, or may not be provided in the uppermost metal layer.

The memory device 1400 may include an upper metal pattern 1372a and a lower metal pattern 1273a, which are provided in the outer pad bonding region PA, and, in some implementations, the lower metal pattern 1273a may be formed in the uppermost metal layer of the peripheral circuit structure PERI to correspond to the upper metal pattern 1372a, which is formed in the uppermost metal layer of the cell array structure CELL, or to have the same shape as the upper metal pattern 1372a of the cell array structure CELL. The lower metal pattern 1273a, which is formed in the uppermost metal layer of the peripheral circuit structure PERI, may not be connected to any contact plug in the peripheral circuit structure PERI. Similarly, in the outer pad bonding region PA, the upper metal pattern 1372a may be formed in the uppermost metal layer of the cell array structure CELL to correspond to the lower metal pattern 1273a, which is formed in the uppermost metal layer of the peripheral circuit structure PERI, and in this case, the upper metal pattern 1372a may have the same shape as the lower metal pattern 1273a of the peripheral circuit structure PERI.

The lower bonding metals 1271b and 1272b may be formed on the second metal layer 1240b of the word line bonding region WLBA. In the word line bonding region WLBA, the lower bonding metals 1271b and 1272b of the peripheral circuit structure PERI may be electrically connected to the upper bonding metals 1371b and 1372b of the cell array structure CELL in a bonding manner.

Furthermore, in the bit line bonding region BLBA, an upper metal pattern 1392 may be formed in the uppermost metal layer of the cell array structure CELL to correspond to a lower metal pattern 1252, which is formed in the uppermost metal layer of the peripheral circuit structure PERI, and in this case, the upper metal pattern 1392 may have the same shape as the lower metal pattern 1252 of the peripheral circuit structure PERT. In some implementations, any contact plug may not be formed on the upper metal pattern 1392, which is formed in the uppermost metal layer of the cell array structure CELL.

According to some implementations of the present disclosure, for a semiconductor memory device, in which a ferroelectric layer is used as a data storage element, a word line and a back-gate electrode in each memory cell may be provided to have an asymmetric structure. A ferroelectric layer and a vertical channel may be provided between the word line and the back-gate electrode.

Based on at least some implementations of the present disclosure, it may be possible to separate a read path from a write path during an operation of a semiconductor memory device. Furthermore, due to a body effect, it may be possible to realize a wide memory window and thereby to realize a multibit operation of a unit memory cell.

While example implementations of the present disclosure have been particularly shown and described, it will be understood by one of ordinary skill in the art that variations in form and detail may be made therein without departing from the spirit and scope of the attached claims.

1. A semiconductor memory device, comprising:
a vertical channel extending perpendicular to a top surface of a substrate;
a plurality of word lines disposed on a first side of the vertical channel and vertically stacked on the substrate;
a plurality of back-gate electrodes disposed on a second side of the vertical channel and vertically stacked on the substrate, wherein the second side is opposite the first side;
a ferroelectric layer disposed between the word lines and the vertical channel;
a first intermediate insulating layer disposed between the ferroelectric layer and the vertical channel; and
a second intermediate insulating layer disposed between the plurality of back-gate electrodes and the vertical channel.

2. The semiconductor memory device of claim 1, wherein the plurality of word lines and the plurality of back-gate electrodes extend in a first direction that is parallel to the top surface of the substrate.

3. The semiconductor memory device of claim 2, further comprising a plurality of insulating isolation patterns disposed between the plurality of word lines and the plurality of back-gate electrodes,
wherein the plurality of insulating isolation patterns are spaced apart from one another in the first direction, and
wherein the vertical channel is disposed between a first insulating isolation pattern of the plurality of insulating isolation patterns and a second insulating isolation pattern of the plurality of insulating isolation patterns.

4. The semiconductor memory device of claim 2, wherein the plurality of word lines partially enclose the vertical channel, when viewed in a plan view.

5. The semiconductor memory device of claim 4, wherein the second intermediate insulating layer extends in the first direction and covers side surfaces of the plurality of word lines.

6. The semiconductor memory device of claim 1, wherein a thickness of the second intermediate insulating layer is larger than a thickness of the first intermediate insulating layer.

7. The semiconductor memory device of claim 1, wherein the plurality of word lines and the plurality of back-gate electrodes comprise the same conductive material.

8. The semiconductor memory device of claim 1, wherein the plurality of word lines and the plurality of back-gate electrodes comprise impurity-doped polysilicon.

9. A semiconductor memory device, comprising:
a first stack disposed on a substrate and extending in a first direction, the first stack comprising a plurality of word lines which are vertically stacked;
a second stack disposed on the substrate and extending in the first direction, the second stack including a plurality of back-gate electrodes which are vertically stacked;
a plurality of vertical channels between the first stack and the second stack, the plurality of vertical channels spaced apart from one another in the first direction;
a plurality of ferroelectric layers disposed between the plurality of vertical channels and the first stack;
a plurality of first intermediate insulating layers disposed between the ferroelectric layer and the plurality of vertical channels; and
a plurality of second intermediate insulating layers disposed between the plurality of vertical channels and the second stack.

10. The semiconductor memory device of claim 9, further comprising a plurality of second ferroelectric layers disposed between the second stack and the second intermediate insulating layers.

11. The semiconductor memory device of claim 9, wherein the plurality of second intermediate insulating layers are in direct contact with a side surface of the second stack.

12. The semiconductor memory device of claim 9, wherein a thickness of at least one of the plurality of second intermediate insulating layers is larger than a thickness of at least one of the plurality of first intermediate insulating layers.

13. The semiconductor memory device of claim 9, further comprising insulating isolation patterns disposed between adjacent vertical channels of the plurality of vertical channels in the first direction.

14. The semiconductor memory device of claim 9, further comprising a plurality of bit lines extending in a second direction to cross the first stack and the second stack,
wherein the plurality of vertical channels are disposed between the plurality of bit lines and the substrate and are connected to the plurality of bit lines and to the substrate.

15. A semiconductor memory device, comprising:
a first stack disposed on a substrate and extending in a first direction, the first stack comprising vertically-stacked word lines;
a second stack disposed on the substrate and extending in the first direction, the second stack comprising vertically-stacked back-gate electrodes;
a vertical insulating layer disposed between the first stack and the second stack and extending in the first direction; and
a plurality of vertical structures that penetrate the first stack,
wherein each of the plurality of vertical structures comprises:
a vertical channel extending perpendicular to a top surface of the substrate;
a ferroelectric layer between the vertical channel and the first stack; and
an intermediate insulating layer between the ferroelectric layer and the vertical channel,
wherein the plurality of vertical structures have first side surfaces that are in contact with the vertical insulating layer.

16. The semiconductor memory device of claim 15, wherein the first side surfaces of the plurality of vertical structures are aligned with a side surface of the first stack.

17. The semiconductor memory device of claim 15, wherein the plurality of vertical structures are arranged in a zigzag shape in the first direction.

18. The semiconductor memory device of claim 15, wherein the first stack partially encloses each of the plurality of vertical structures, when viewed in a plan view.

19. The semiconductor memory device of claim 15, wherein the vertical channel of each of the plurality of vertical structures has a circular segment section.

20. The semiconductor memory device of claim 15, further comprising a first separation structure and a second separation structure, wherein the first separation structure and the second separation structure extend in the first direction parallel to one another, and
wherein the first stack and the second stack are disposed between the first separation structure and the second separation structure.

21. (canceled)
